(19) United States
(12) Patent Application Publication
(10) Pub. No.: US 2024/0168373 A1
(43) Pub. Date: May 23, 2024

(54) PHOTORESIST AND FORMATION METHOD THEREOF

(71) Applicants: Taiwan Semiconductor Manufacturing Company, Ltd., Hsinchu (TW); National Tsing Hua University, Hsinchu City (TW)

(72) Inventors: Jui-Hsiung LIU, Taipei City (TW); Tsai-Sheng GAU, Hsinchu City (TW); Burn Jeng LIN, Hsinchu City (TW); Yan-Ru WU, New Taipei City (TW); Ting-An LIN, Taoyuan City (TW); Han-Tsung TSAI, New Taipei City (TW); Po-Hsiung CHEN, Taichung City (TW)

(73) Assignees: Taiwan Semiconductor Manufacturing Company, Ltd., Hsinchu (TW); National Tsing Hua University, Hsinchu City (TW)

(21) Appl. No.: 18/333,815

(22) Filed: Jun. 13, 2023

Related U.S. Application Data
(60) Provisional application No. 63/415,025, filed on Oct. 11, 2022.

(51) Int. Cl. G03F 7/004; G03F 7/20

(52) U.S. Cl. CPC G03F 7/0042; G03F 7/2004; G03F 7/201

(57) ABSTRACT

A photoresist composition includes a mixture. The mixture includes a first photosensitive material and a second photosensitive material. The first photosensitive material is a 6-Sn oxide cluster, a 12-Sn oxide cluster or a combination thereof. The second photosensitive material has a composition being different from a composition of the first photosensitive material.

### RELATED APPLICATIONS

This application claims priority to U.S. Provisional Patent Application Ser. No. 63/415,025, filed Oct. 11, 2022, which is herein incorporated by reference in its entirety.

### BACKGROUND

As modern integrated circuits shrink in size, the associated features shrink in size as well. Lithography is a mechanism by which a pattern on a mask is projected onto a substrate such as a semiconductor wafer. In areas such as semiconductor photolithography, it has become necessary to create images on the semiconductor wafer which incorporate minimum feature sizes under a resolution limit or critical dimension (CD). Semiconductor photolithography typically includes the steps of applying a coating of photoresist (also referred to as resist) on a top surface (e.g., a thin film stack) of a semiconductor wafer and exposing the photoresist to a pattern. The semiconductor wafer is then transferred to a developing chamber to remove the exposed resist, which is soluble to an aqueous developer solution. As a result, a patterned layer of photoresist exists on the top surface of the wafer.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a schematic view of an EUV lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIG. 1C is a sectional view of a EUV mask constructed in accordance with some embodiments of the present disclosure.

FIG. 2 is a flow chart diagram of a method of fabricating a semiconductor device using a photoresist layer according to various aspects of the present disclosure.

FIG. 3 illustrates a fragmentary cross-sectional side view of the semiconductor device corresponding to the flow chart diagram in FIG. 2 in accordance with various aspects of the present disclosure.

FIGS. 4A-4D show cross-sectional views of photoresist layers with different curable compositions over a substrate in accordance with some embodiments.

FIG. 5 is a diagram showing contrast curves of a resist thickness versus a dose energy of an E-beam in accordance with some embodiments.

FIGS. 6 and 7 illustrate fragmentary cross-sectional side views of the semiconductor device corresponding to the flow chart diagram in FIG. 2 in accordance with various aspects of the present disclosure.

FIG. 8A is a diagram showing a contrast curve of a resist thickness versus a dose energy of an E-beam in accordance with some embodiments.

FIG. 8B shows a cross-sectional view of a photoresist layer over a substrate in accordance with some embodiments.

FIG. 9 illustrates a fragmentary cross-sectional side view of the semiconductor device corresponding to the flow chart diagram in FIG. 2 in accordance with various aspects of the present disclosure.

FIGS. 10-15 illustrate fragmentary cross-sectional side views of the semiconductor device in accordance with some other embodiments of the present disclosure.

FIGS. 16, 17, 18, 19, 20, 21, 22, 23 and 24A illustrate perspective views of additional fabrication processes in the formation of a semiconductor device on a substrate in accordance with some embodiments of the present disclosure.

FIGS. 24B, 25, 26 and 27 illustrate cross-sectional views of additional fabrication processes in the formation of a semiconductor device using a substrate in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

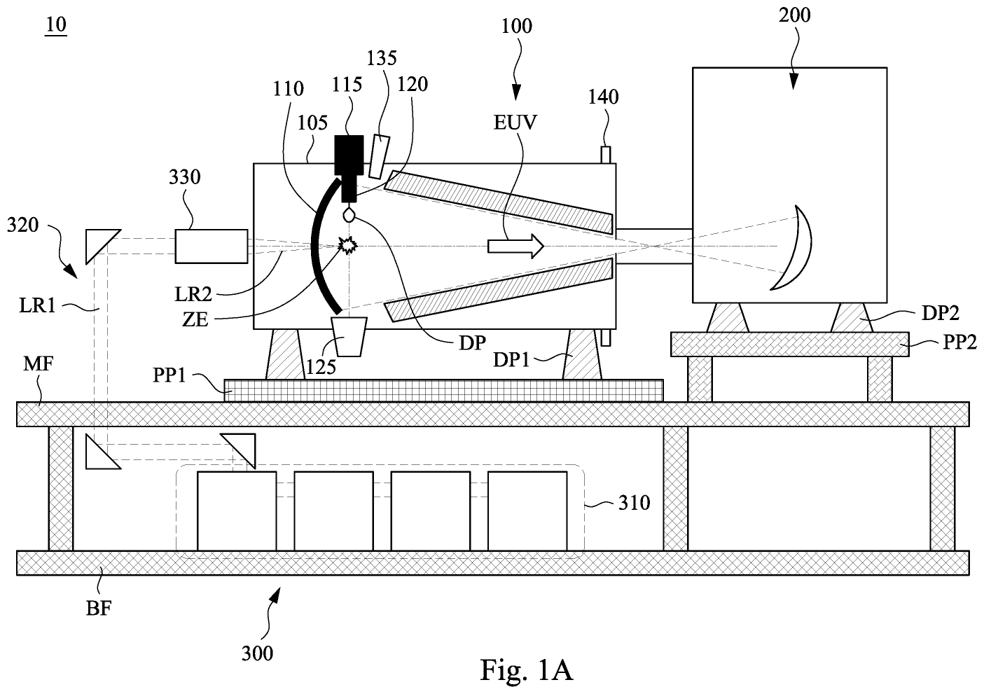

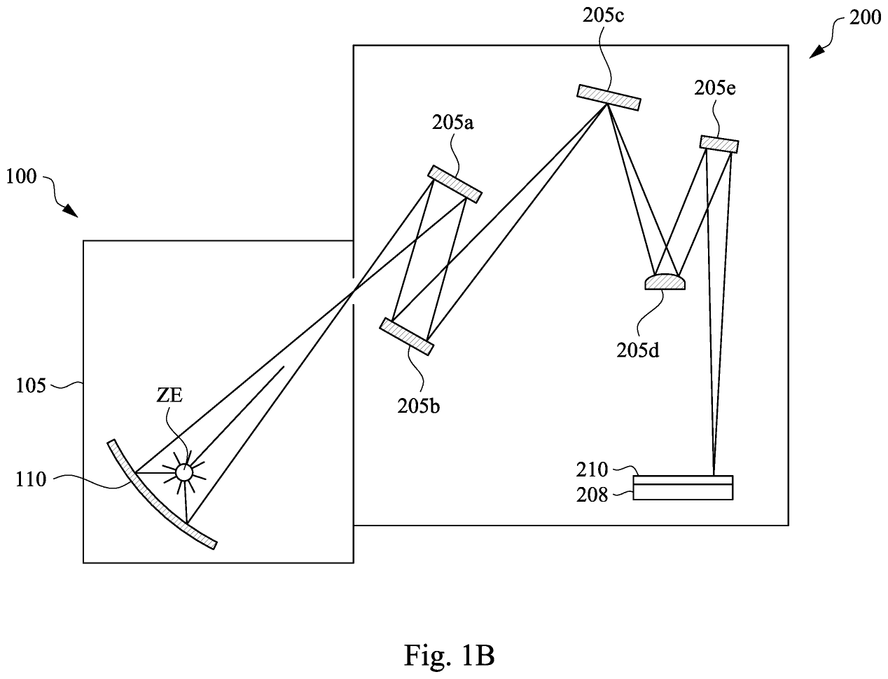

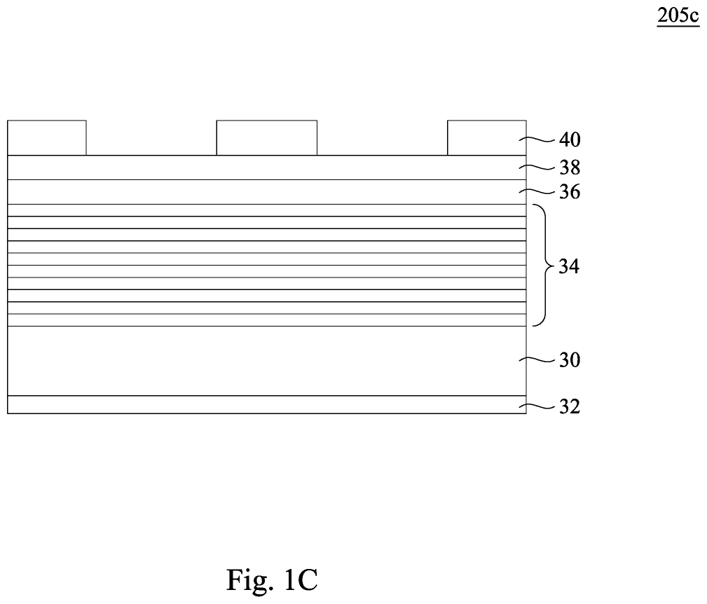

FIG. 1A is a schematic view diagram of an EUV lithography system 10, constructed in accordance with some embodiments. The EUV lithography system 10 may also be generically referred to as a scanner that is configured to perform lithography exposure processes with respective radiation source and exposure mode. The EUV lithography system 10 is designed to expose a photoresist layer by an EUV light or EUV radiation. The photoresist layer is a material sensitive to the EUV light. The EUV lithography system 10 employs a radiation source 100 to generate EUV light, such as EUV light having a wavelength ranging between about 1 nm and about 100 nm. In one particular example, the radiation source 100 generates a EUV light with a wavelength centered at about 13.5 nm. Accordingly, the radiation source 100 is also referred to as EUV radiation source 100.

Extreme ultraviolet (EUV) lithography has become widely used due to its ability to achieve small semiconductor device sizes, for example for 20 nanometer (nm) technology nodes. Metal oxide based photoresists, such as 12-Sn oxide clusters, exhibit good absorption of far ultraviolet light at a 193 nm wavelength and extreme ultraviolet light at a 13.5 nm wavelength, being more efficient than organic polymers in EUV absorptions. Although metal oxide based photoresists have nice lithographic patterns, they are sensitive to water and air, and thus a costly formulation to remove water residues is required. Strict operations to exclude air and/or moisture are required as well.

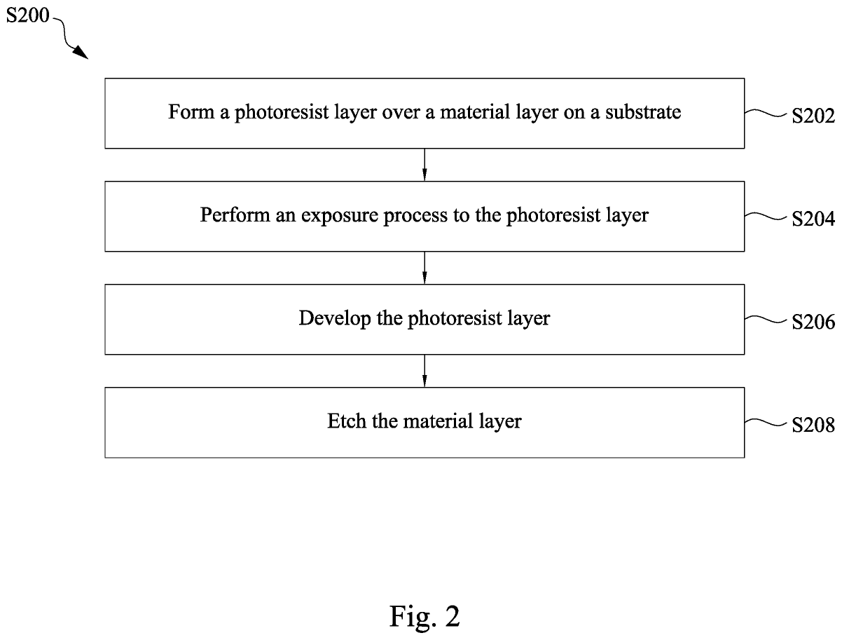

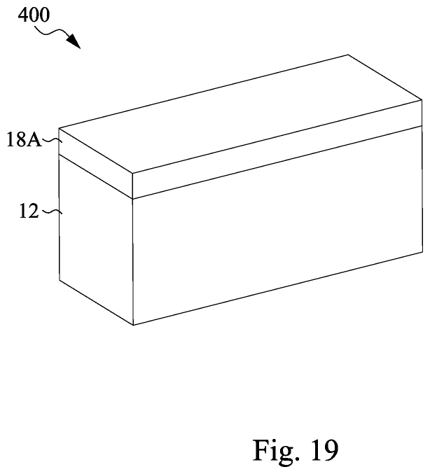

The present disclosure provides a novel photoresist having a photoresist composition including a mixture. The novel photoresist can be formed into a film with a smooth surface morphology that is stable with air and water. The various aspects of the present disclosure will be discussed below in greater detail with reference to FIGS. 1A-27. First, an EUV lithography system will be discussed below with reference to FIGS. 1A, 1B and 1C. Next, the details of the novel photoresist and the lithography process employing the photoresist will be discussed with reference to FIGS. 2-27.

The advanced lithography process, method, and materials described in the current disclosure can be used in many applications, including fin-type field effect transistors (FinFETs), gate-all-around (GAA) FETs. For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LPP) are collected by a collector mirror and reflected toward a patterned mask.

FIG. 1A is a schematic view of an EUV lithography tool with an LPP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the EUV radiation source 100 to generate EUV light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1C, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength. In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 μm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a ML (such as a plurality of Mo/Si film pairs) and may further include a capping layer (such as Ru) coated on the ML to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML deposited on the substrate. The ML includes a plurality of film pairs, such as molybdenum-silicon (Mo/Si) film pairs (e.g., a layer of molybdenum above or below a layer of silicon in each film pair). Alternatively, the ML may include molybdenum-beryllium (Mo/Be) film pairs, or other suitable materials that are configurable to highly reflect the EUV light.

The mask 205c may further include a capping layer, such as ruthenium (Ru), disposed on the ML for protection. The mask 205c further includes an absorption layer deposited over the ML. The absorption layer is patterned to define a layer of an integrated circuit (IC), the absorber layer is discussed below in greater detail according to various aspects of the present disclosure. Alternatively, another reflective layer may be deposited over the ML and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of the reflective mask 205c is shown in FIG. 1C. The reflective mask 205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the LTEM substrate 30 for the electrostatic chucking purpose. In one example, the conductive layer 32 includes chromium nitride (CrN), though other suitable compositions are possible.

The reflective mask 205c includes a reflective multilayer (ML) structure 34 disposed over the LTEM substrate 30. The ML structure 34 may be selected such that it provides a high reflectivity to a selected radiation type/wavelength. The ML structure 34 includes a plurality of film pairs, such as Mo/Si film pairs (e.g., a layer of molybdenum above or below a layer of silicon in each film pair). Alternatively, the ML structure 34 may include Mo/Be film pairs, or any materials with refractive index difference being highly reflective at EUV wavelengths.

Still referring to FIG. 1C, the EUV mask 205c also includes a capping layer 36 disposed over the ML structure 34 to prevent oxidation of the ML. The EUV mask 205c may further include a buffer layer 38 disposed above the capping layer 36 to serve as an etching-stop layer in a patterning or repairing process of an absorption layer, which will be described later. The buffer layer 38 has different etching characteristics from the absorption layer disposed thereabove. The buffer layer 38 includes ruthenium (Ru), Ru compounds such as RuB, RuSi, chromium (Cr), chromium oxide, and chromium nitride in various examples.

The EUV mask 205c also includes an absorber layer 40 (also referred to as an absorption layer) formed over the buffer layer 38. In some embodiments, the absorber layer 40 absorbs the EUV radiation directed onto the mask. In various embodiments, the absorber layer may be made of tantalum boron nitride (TaBN), tantalum boron oxide (TaBO), or chromium (Cr), Radium (Ra), or a suitable oxide or nitride (or alloy) of one or more of the following materials: Actium, Radium, Tellurium, Zinc, Copper, and Aluminum.

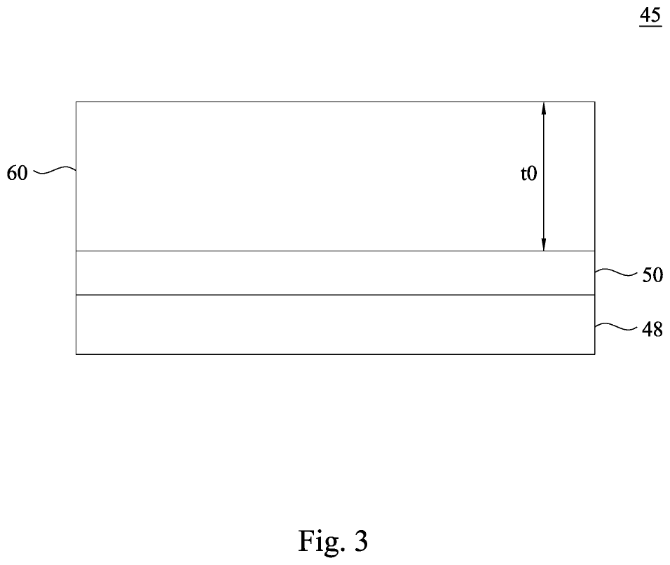

FIG. 2 is a flow chart diagram of a method S200 of fabricating a semiconductor device 45 using a photoresist layer according to various aspects of the present disclosure. FIGS. 3, 6, 7 and 12 illustrate fragmentary cross-sectional side views of the semiconductor device 45 corresponding to the flow chart diagram in FIG. 2 in accordance with various aspects of the present disclosure. Referring to block S202 of FIG. 2 and to FIG. 3, a photoresist layer 60 is formed over a material layer 50 on a substrate 48. The semiconductor device 45 may include an integrated circuit (IC) chip, system on chip (SoC), or portion thereof, and may include various passive and active microelectronic devices such as resistors, capacitors, inductors, diodes, metal-oxide semiconductor field effect transistors (MOSFET), complementary metal-oxide semiconductor (CMOS) transistors, bipolar junction transistors (BJT), laterally diffused MOS (LDMOS) transistors, high power MOS transistors, or other types of transistors.

In some embodiments, the substrate 48 is a silicon substrate doped with a p-type dopant such as boron (for example a p-type substrate). Alternatively, the substrate 48 could be another suitable semiconductor material. For example, the substrate 48 may be a silicon substrate that is doped with an n-type dopant such as phosphorous or arsenic (an n-type substrate). The substrate 48 could include other elementary semiconductors such as germanium and diamond. The substrate 48 could optionally include a compound semiconductor and/or an alloy semiconductor. Further, the substrate 48 could include an epitaxial layer (epi layer), may be strained for performance enhancement, and may include a silicon-on-insulator (SOI) structure.

In some embodiments, the substrate 48 is substantially conductive or semi-conductive. The electrical resistance may be less than about 10³ ohm-meter. In some embodiments, the substrate 48 contains metal, metal alloy, or metal nitride/sulfide/selenide/oxide/silicide with the formula MXₐ, where M is a metal, and X is N, S, Se, O, Si, and where “a” is in a range from about 0.4 to 2.5. For example, the substrate 48 may contain Ti, Al, Co, Ru, TiN, WN₂, or TaN.

In some other embodiments, the substrate 48 contains a dielectric material with a dielectric constant in a range from about 1 to about 40. In some other embodiments, the substrate 48 contains Si, metal oxide, or metal nitride, where the formula is MX_{b}, wherein M is a metal or Si, and X is N or O, and wherein “b” is in a range from about 0.4 to 2.5. For example, the substrate 48 may contain SiO₂, silicon nitride, aluminum oxide, hafnium oxide, or lanthanum oxide.

The material layer 50 can be patterned via a lithography process and as such may also be referred to as a patternable layer. In an embodiment, the material layer 50 includes a dielectric material, such as silicon oxide or silicon nitride. In another embodiment, the material layer 50 includes metal. In yet another embodiment, the material layer 50 includes a semiconductor material.

In some embodiments, the material layer 50 has different optical properties than photoresist. For example, the material layer 50 has a different n, k, or T value from photoresist. In some embodiments, the material layer 50 and the overlying photoresist layer have different etching resistance. In some embodiments, the material layer 50 contains an etching resistant molecule. It is understood that the substrate 48 and the material layer 50 may each include additional suitable material compositions in other embodiments.

The photoresist layer 60 may be formed by a spin-coating process. In some embodiments, the photoresist layer 60 can be spin coated on the material layer 50 on the substrate 48. In many instances, the substrate 48 when in the form of a wafer can have a diameter of 1-inch (25 mm); 2-inch (51 mm); 3-inch (76 mm); 4-inch (100 mm); 5-inch (130 mm) or 125 mm (4.9 inch); 150 mm (5.9 inch, usually referred to as “6 inch”); 200 mm (7.9 inch, usually referred to as “8 inch”); 300 mm (11.8 inch, usually referred to as “12 inch”); or 450 mm (17.7 inch, usually referred to as “18 inch”); for example. For example, a composition of the photoresist layer 60 is placed (dispensed) on the substrate 48. The photoresist layer 60 may then be baked. In some embodiments, the photoresist layer 60 has a thickness t0 in a range from 20 nm to 25 nm.

The photoresist layer 60 has a curable composition such as a photo-curable composition. The photo-curable composition is a mixture (e.g., a curable mixture or a curable blend). The mixture includes a first photosensitive material and at least one of a second photosensitive material, a third photosensitive material, or a fourth photosensitive material. In some embodiments, the curable composition of the photoresist layer 60 may include a solvent. The mixture is dissolved in the solvent. The solvent includes an appropriate organic solvent for an adjustment of its viscosity. Such organic solvent includes, but is not limited to, 4-methyl-2-pentanol. In some embodiments, the mixture is in an amount from about 1.2 weight percentage (wt %) to about 2 wt % with respect to a weight of the photoresist layer 60. In certain embodiment, the mixture is in an amount from about 1.2 wt % to about 1.5 wt % with respect to the weight of the photoresist layer 60. If the mixture has a concentration lower than about 1.2 wt %, the photoresist layer 60 may have an increased fluidity, which may contaminate the underlying layers, and the photoresist layer 60 may have a non-uniform top surface. If the mixture has a concentration higher than about 2 wt %, the photoresist layer 60 may have a rough top surface. In another example, the curable composition of the photoresist layer 60 may include an acid labile molecule, a polymer, photoacid generator (PAG), quencher, chromophore, crosslinker, surfactant, or a combination thereof.

The second, third, and fourth photosensitive materials are different from the first photosensitive material. For example, the second, third, and fourth photosensitive materials have more irregular structures than a structure of the first photosensitive material. In certain embodiments, the first, second, third and fourth photosensitive materials are metal-based clusters. For example, the first photosensitive material is a 6-Sn oxide cluster, a 12-Sn oxide cluster, or a combination thereof. In some embodiments where the first photosensitive material is 12-Sn oxide cluster, an illustrative example of the first photosensitive material may be represented by formula (A):

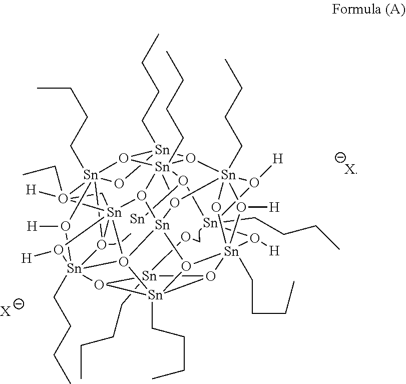

X in the Formula (A) represents OH, Cl, Br, BF₄, 0.5C₂O₄, or RCO₂, CF₃SO₃, and in the RCO₂, R has 1 to 15 carbon atoms.

In some embodiments where the first photosensitive material is a 6-Sn oxide cluster, an illustrative example of the first photosensitive material may be represented by formula (B):

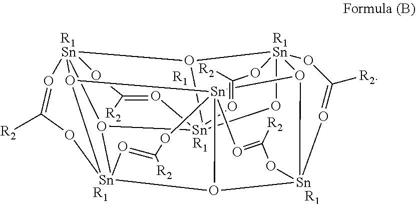

R₁ in the formula (B) represents —CH₃ or is represented by one of formulae (M-1) to (M-3):

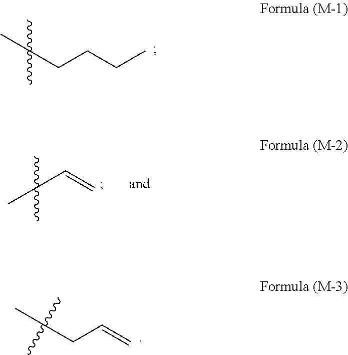

R₂ in the formula (B) can be represented by one of formulae (M-4) to (M-10):

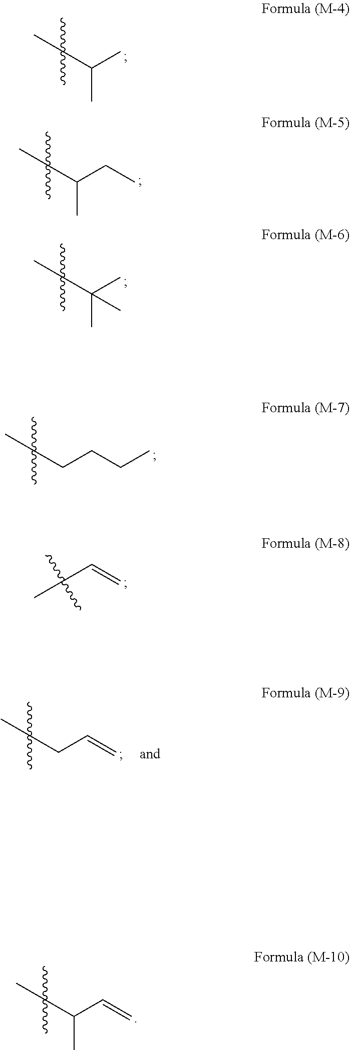

In some embodiments, the first photosensitive material is represented by formula (Ba):

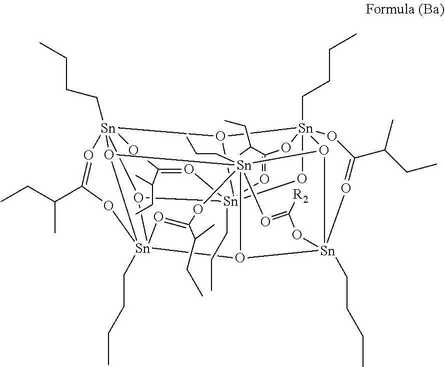

where the R₁ in the formula (B) is represented by the formula (M-1), which is a butyl group (Bu), and R₂ in the formula (B) is represented by the formula (M-5). In some embodiments, the second photosensitive material has a 6Sn-2Cl structure. For example, the second photosensitive material is a 6Sn(vinyl)-2Cl cluster. In other words, a vinyl moiety is attached to the Sn atoms in the 6Sn(vinyl)-2Cl cluster. That is, the second photosensitive material incudes Sn-vinyl units. The Sn-vinyl units provide high photosensitivity, and thus a low energy dose of EUV radiation to expose the photoresist layer 60 is required. The second photosensitive material may be represented by formula (1):

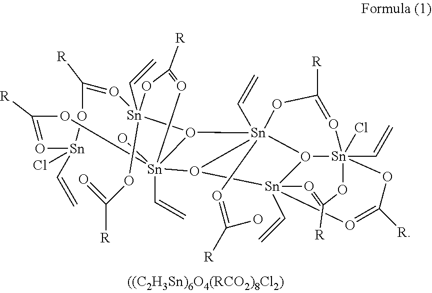

Illustrative examples of R in the Formula (1) can be represented by one of formulae (I-1) to (I-7):

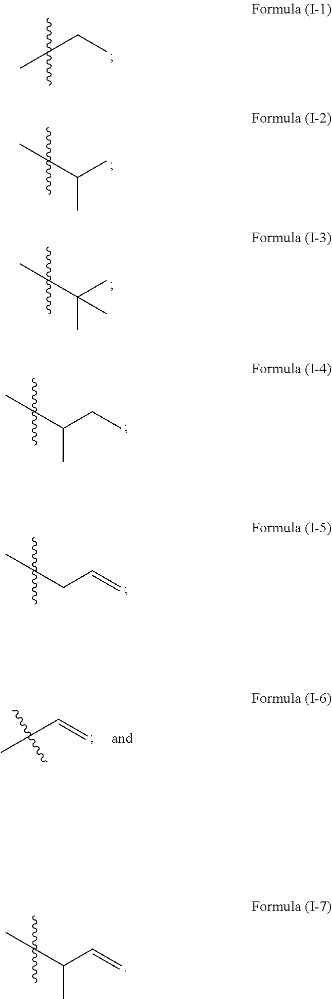

As shown in the formula (1), the second photosensitive material has an irregular structure, and thus can enhance a smooth surface morphology for the photoresist layer 60.

In some embodiments where the second photosensitive material is represented by the formula (1), the second photosensitive material can be synthesized by a reaction shown in the following general reaction scheme 1-1:

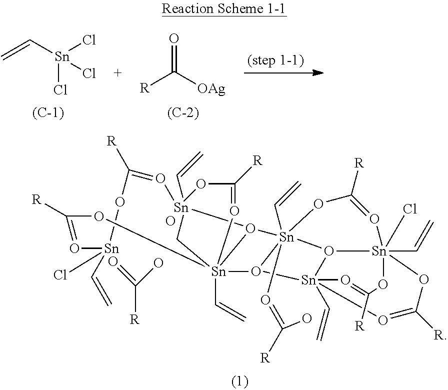

In the reaction scheme 1-1, a first compound is represented by formula (C-1):

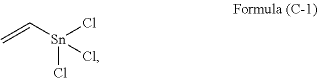

and a second compound is represented by formula (C-2):

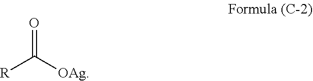

R in the formula (C-2) can be represented by one of the formulae (I-1) to (I-7) as discussed above. The first compound reacts with the second compound in a solvent. For example, a reflux reaction is performed to the first compound and the second compound in the solvent for 7-9 hours, such as 8 hours. An example of the appropriate solvent for the reaction scheme 1-1 is CH₂Cl₂. In some embodiments, a 1.0 (±0.1) eq of the first compound and a 2.5 (±0.1) eq of the second compound were added in the solvent. A product of the reaction scheme 1-1 has a structure which can be characterized by X-ray diffraction (XRD) and element analysis (EA) data. In some embodiments where R of the second compound is represented by the formula (I-4):

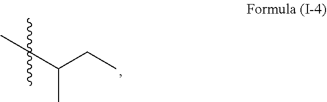 [SMILES: *C(C)CC]

the product of the reaction scheme 1-1 is represented by a formula (1a):

(C₂H₃Sn)₆O₄(C₄H₉CO₂)₈Cl₂ Formula (1a).

A structural formula thereof may be represented by formula (J-2′):

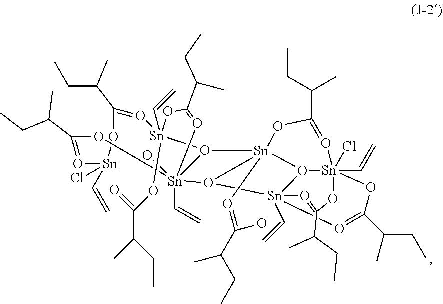

which is a 6Sn(vinyl)-2Cl ladder structure.

In some embodiments, the third photosensitive material has a 5Sn-5Cl structure, and the fourth photosensitive material has a 5Sn-5Cl structure as well. The third photosensitive material may be represented by formula (2):

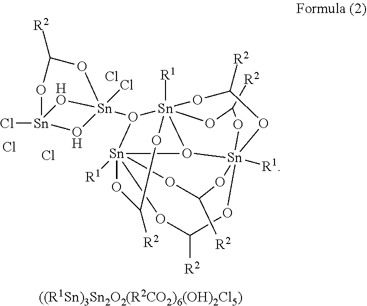

R¹ in the formula (2) can be represented by formula (L-1):

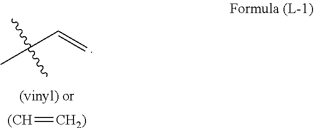

A vinyl moiety is attached to some of the Sn atoms in the Formula (2). That is, the third photosensitive material incudes Sn-vinyl units. The Sn-vinyl units provide high photosensitivity, and thus a low energy dose of EUV radiation to expose the photoresist layer 60 is required. Illustrative examples of R² in the Formula (2) can be represented by one of formulae (K-1) to (K-6):

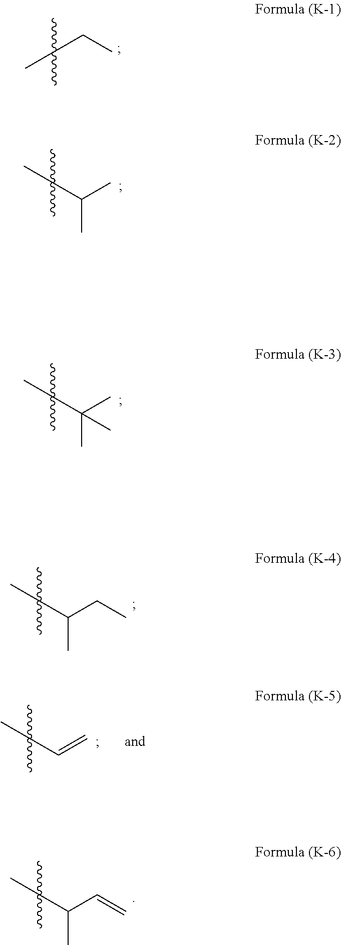

As shown in the formula (2), the third photosensitive material has an irregular structure, and thus can enhance a smooth surface morphology for the photoresist layer 60.

In some embodiments where the third photosensitive material is represented by the formula (2), the third photosensitive material can be synthesized by a reaction shown in the following general reaction scheme 1-2:

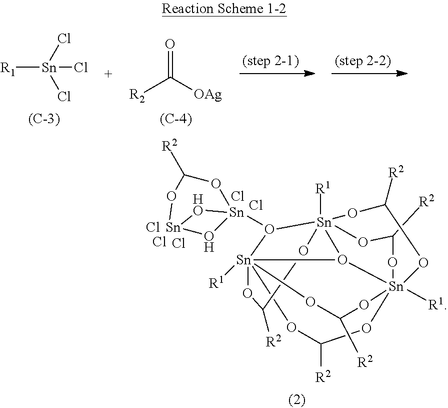

In the reaction scheme 1-2, a first compound is represented by formula (C-3):

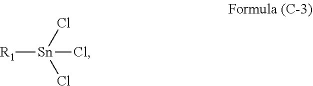

in the formula (C-3), R₁ is represented by formula (L-1):

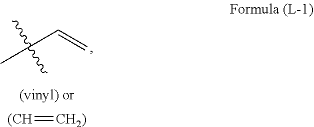

and a second compound is represented by formula (C-4):

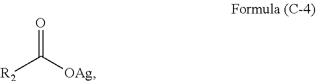

in the formula (C-4), R₂ is represented by one of the formulae (K-1) to (K-6) as discussed above. In a step 2-1 of the reaction scheme 1-2, the first compound reacts with the second compound in a solvent. For example, a reflux reaction is performed to the first compound and the second compound in the solvent for 7-9 hours, such as 8 hours to obtain a substance. After the step 2-1, a step 2-2 is performed. The step 2-2 is a recrystallization step. For example, during the step 2-2, a substance (i.e., a product) from the step 2-1 is recrystallized to yield the third photosensitive material represented by the formula (2). An example of the appropriate solvent for the step 2-1 in the reaction scheme 1-2 is CH₂Cl₂. In some embodiments, a 1.0 (±0.1) eq of the first compound and a 2.0 (±0.1) eq of the second compound are added in the solvent.

In some embodiments where R₂ of the formula (C-4) of the second compound is represented by the formula (K-3):

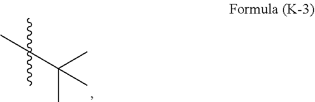 [SMILES: *C(C)(C)C]

the product of the reaction scheme 1-2 is represented by a formula (2a):

(vinyl-Sn)₃Sn₂O₂(C₄H₉CO₂)₆(OH)₂Cl₅ Formula (2a).

A structural formula thereof may be represented by formula (J-3′):

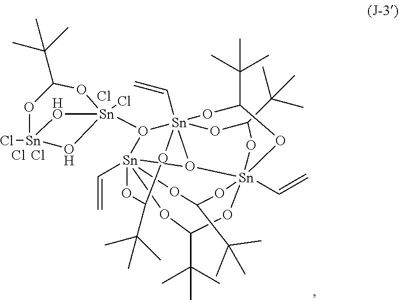

which is a 5Sn(vinyl)-5Cl cluster structure.

The fourth photosensitive material may be represented by formula (3):

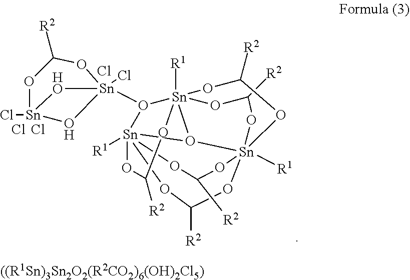

R¹ in the formula (3) can be represented by formula (L-2):

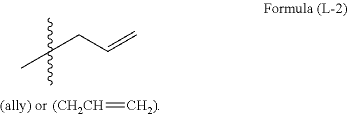

An allyl moiety is attached to some of the Sn atoms in the Formula (3). That is, the fourth photosensitive material incudes Sn-allyl units. The Sn-allyl units provide high photosensitivity, and thus a low energy dose of EUV radiation to expose the photoresist layer 60 is required. Illustrative examples of R² in the Formula (2) can be —CH₃ or can be represented by one of the formulae (K-1) to (K-6) as discussed above. As shown in the formula (3), the fourth photosensitive material has an irregular structure, and thus can enhance a smooth surface morphology for the photoresist layer 60.

In some embodiments where the fourth photosensitive material is represented by the formula (3), the fourth photosensitive material can be synthesized by a reaction shown in the following general reaction scheme 1-3:

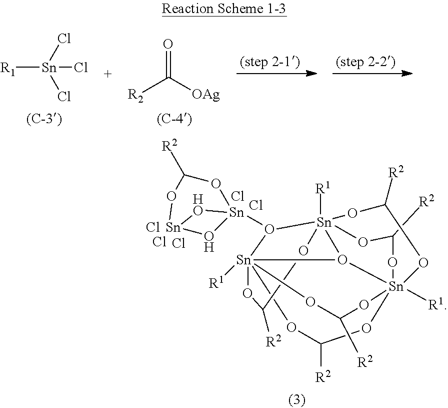

In the reaction scheme 1-3, a first compound is represented by formula (C-3′):

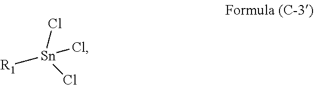

in the formula (C-3′), R₁ is represented by formula (L-2):

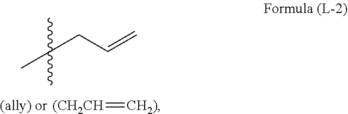

and a second compound is represented by formula (C-4′):

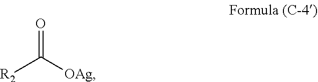

in the formula (C-4′), R₂ represents CH₃ or is represented by one of the formulae (K-1) to (K-6) as discussed above. In a step 2-1′ of the reaction scheme 1-3, the first compound reacts with the second compound in a solvent. For example, a reflux reaction is performed to the first compound and the second compound in the solvent for 7-9 hours, such as 8 hours to obtain a substance. After the step 2-1′, a step 2-2′ is performed. The step 2-2′ is a recrystallization step. For example, during the step 2-2′, a substance (i.e., a product) from the step 2-1′ is recrystallized to yield the third photosensitive material represented by the formula (3). An example of the appropriate solvent for the reaction scheme 1-3 is CH₂Cl₂. In some embodiments, a 1.0 (±0.1) eq of the first compound and a 3.0 (±0.1) eq of the second compound are added in the solvent.

In some embodiments where R² of the second compound represents CH₃, the product of the reaction scheme 1-3 is represented by formula (3a):

(allyl-Sn)₃Sn₂O₂(CH₃CO₂)₆(OH)₂Cl₅ Formula (3a).

A structural formula thereof may be represented by formula (J-4):

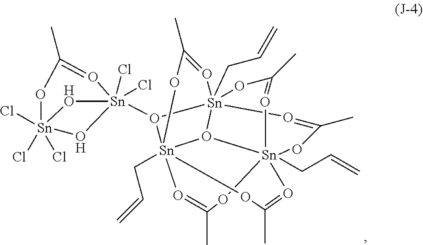

which is a 5Sn(allyl)-5Cl cluster structure.

In certain embodiments, the first photosensitive material is a major component in the mixture of the curable composition of the photoresist layer 60, while the second, third and fourth photosensitive materials are a minor component in the mixture. That is, an amount of the first photosensitive material in the mixture is greater than an amount of the at least one of the second, third and fourth photosensitive materials in the mixture. For example, a weight percentage of the first photosensitive material in the mixture is in a range from 60% to 70%. A weight percentage of the at least one of the second, third and fourth photosensitive materials in the mixture is in a range from 30% to 40%. If the weight percentage of the first compound in the mixture is less than 60%, an exposure dose of the EUV radiation required to expose the photoresist layer 60 may be too high, leading to an increased cost. If the weight percentage of the at least one of the second, third and fourth photosensitive materials in the mixture is greater than 70%, a surface morphology of the photoresist layer may be poor and not smooth enough. In some embodiments where the first photosensitive material is represented by the formula (A), a weight ratio of the first photosensitive material to the at least one of the second, third and fourth photosensitive materials is greater than 2:1. In some other embodiments where the first photosensitive material is represented by the formula (B), a weight ratio of the first photosensitive material to the at least one of the second, third and fourth photosensitive materials is greater than 1.3:1.

The mixture of the curable composition of the photoresist layer 60 is stable with air without formulation. In other words, a costly formulation to remove water residues is not required. Strict operations to exclude air and/or moisture are not required either. Due to the Sn-vinyl units in the second photosensitive material, the Sn-vinyl units in the third photosensitive material or the Sn-allyl units in the fourth photosensitive material, which provides high photosensitivity, a low energy dose of EUV radiation to expose the photoresist layer 60 is required. The Sn—Cl bonds in the second, third and fourth photosensitive materials also enhance the photosensitivity because a Sn—Cl—Sn unit tends to be formed under the EUV radiation. In some embodiments, the photoresist layer 60 can be patterned to have a half-pitch (HP) of 14 nm to 18 nm using a dose of EUV radiation in a range from 40 mJ/cm² to 60 mJ/cm². A regularity of a chemical structure is in positive correlation with a crystallinity of the chemical structure. A decreased crystallinity is beneficial for achieving a smooth surface. The second, third and fourth photosensitive materials each has an irregular structure, providing the photoresist layer 60 a smooth surface morphology. In greater details, the second, third and fourth photosensitive materials each has a chemical structure being more asymmetric with respect to a virtual center of the chemical structure of the corresponding second, third and fourth photosensitive materials than the first photosensitive material do.

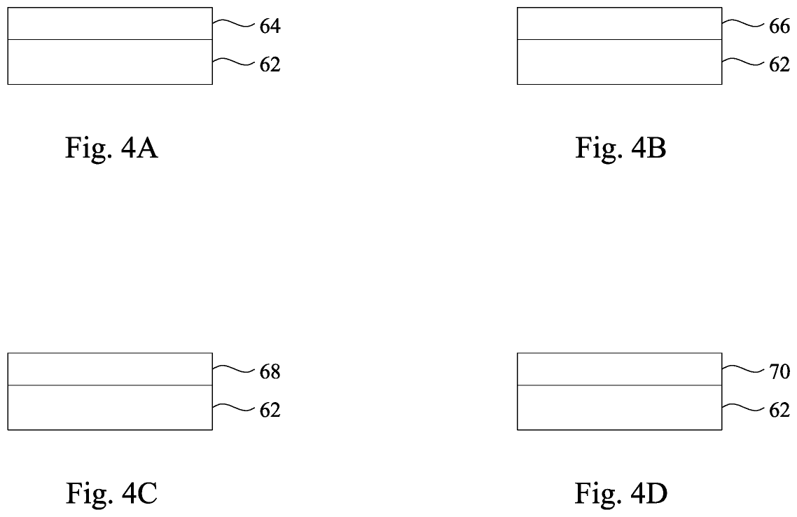

In some embodiments, the curable composition of the photoresist layer 60 may have a mixture (A-1), a mixture (A-2), a mixture (A-3) or a mixture (A-3′). FIGS. 4A-4D show cross-sectional views of photoresist layers with different curable compositions over a substrate in accordance with some embodiments. Reference is made to FIGS. 4A-4D. In some embodiments, mixtures (A-1), (A-2), (A-3), and (A-3′) are formed into films 64, 66, 68, and 70 on a corresponding substrate 62, respectively, using a solution casting method under air. The mixture (A-1) includes the first photosensitive material represented by the formula (A) and the second photosensitive, which is represented by the formula (1). The mixture (A-2) includes the first photosensitive material represented by the formula (A) and the third photosensitive, which is represented by the formula (2). The mixture (A-3) includes the first photosensitive material represented by the formula (A) and the fourth photosensitive, which is represented by the formula (3). The mixture (A-3′) includes the first photosensitive material represented by the formula (A) and the third photosensitive, which is represented by the formula (2). In the mixture (A-1), a weight ratio of the first photosensitive material to the second photosensitive material is about 2:1. In the mixture (A-2), a weight ratio of the first photosensitive material to the third photosensitive material is about 2:1. In the mixture (A-3), a weight ratio of the first photosensitive material to the second photosensitive material is about 2:1. In other words, a weight percentage of the first photosensitive material in the mixture (A-1), (A-2) and (A-3) is about 67%, and a weight percentage of the second, third, or fourth photosensitive materials in the corresponding mixture is about 33%. In the mixture (A-3′), a weight ratio of the first photosensitive material to the third photosensitive material is about 1:1.

In the mixtures (A-1), (A-2), and (A-3), the first photosensitive material is represented by the formula (A) in which X in the formula (A) is CF₃SO₃, OH, or BF₄. For example, the first photosensitive material is represented by the formula (A):

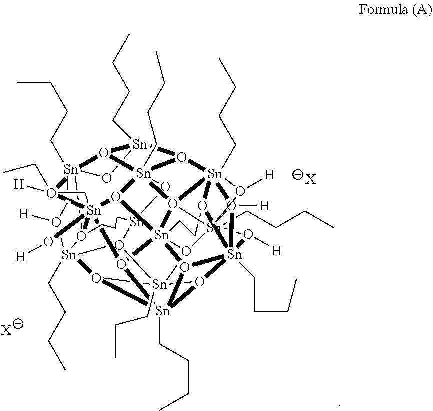

In the mixture (A-3′), the first photosensitive material is represented by the formula (A) in which X in the formula (A) is OH. In the mixture (A-1), the second photosensitive material is represented by the formula (1a):

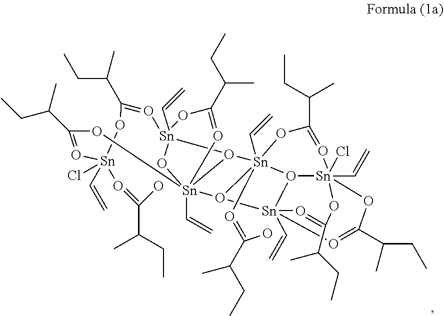

which is a 6Sn(vinyl)-2Cl ladder cluster. In the mixture (A-2), the third photosensitive material is represented by the formula (2a):

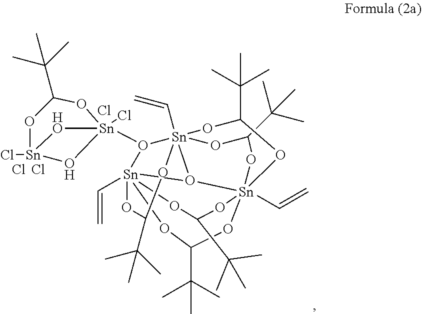

which is a 5Sn(vinyl)-5Cl cluster structure. In the mixture (A-3), the fourth photosensitive material is represented by the formula (3a):

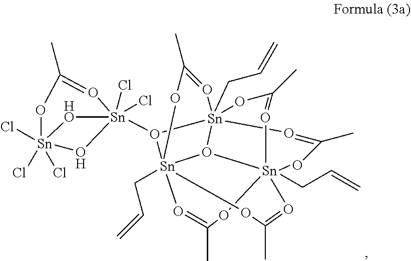

which is a 5Sn(allyl)-5Cl cluster structure. In the mixture (A-3′), the third photosensitive material is represented by the formula (2a).

In some embodiments, the film 64 has a thickness in a range from 20 nm to 25 nm, such as 23 nm. In some embodiments, the film 66 has a thickness in a range from 20 nm to 25 nm, such as 22 nm. In some embodiments, the film 68 has a thickness in a range from 20 nm to 25 nm, such as 22 nm. In some embodiments, the film 70 has a thickness in a range from 20 nm to 25 nm, such as 23 nm.

The films 64, 66, 68, and 70 are smooth over a large area. For example, the films 64, 66, 68, and 70 may have a surface roughness (Rᵣₘₛ) of 0.34 nm to 0.93 nm measured by means of the atomic force microscope (AFM). In some embodiments, the film 64 has a surface roughness of 0.34±0.2 nm, the film 66 has a surface roughness of 0.93±0.2 nm, the film 68 has a surface roughness of 0.50±0.2 nm, and the film 70 has a surface roughness of 0.73±0.2 nm. By using an optical microscopy to identify defects of the films 64, 66, 68 and 70, not defects are observable with a 20× long working distance lens.

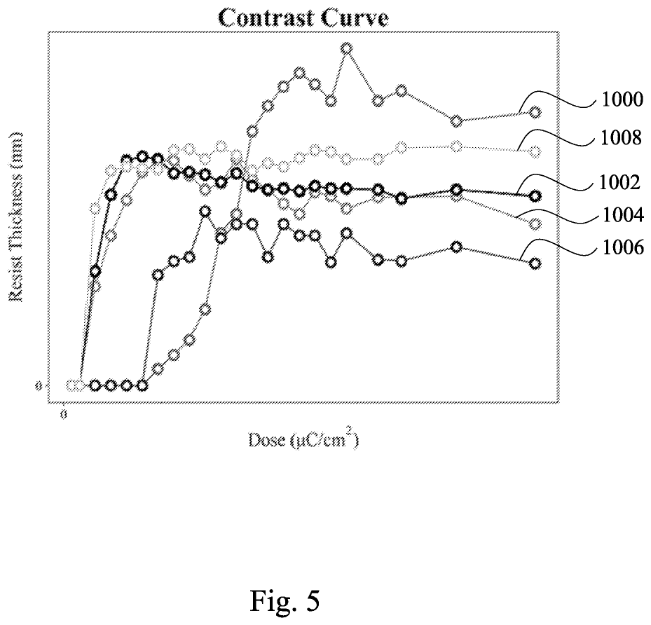

FIG. 5 is a diagram showing contrast curves of a resist thickness versus a dose energy of an E-beam in accordance with some embodiments. In FIG. 5, a curve 1000 shows a resist thickness versus a dose energy in which a resist is the first photosensitive material represented by the formula (A):

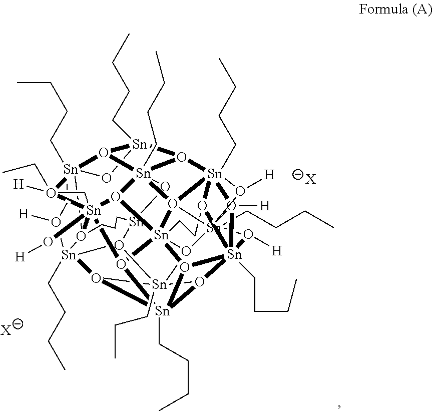

in which X in the formula (A) is CF₃SO₃, OH, or BF₄. Curves 1002, 1004 and 1006 show a resist thickness versus a dose energy in which the corresponding resist is made of the mixtures (A-1), (A-2), and (A-3), respectively. Curve 1008 shows a resist thickness versus a dose energy in which the corresponding resist is made of the second photoresist compound represented by the formula (1a):

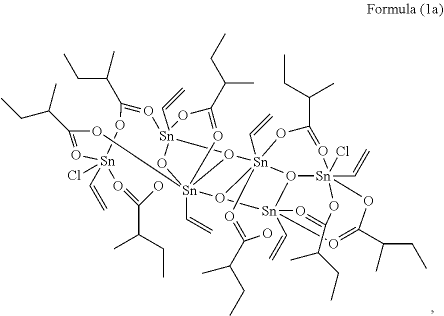

By contrast, in a comparable example which a resist made of only 5Sn-5Cl cluster is too reactive to show a good contrast, and thus cannot be shown in the diagram of FIG. 5. In the curves 1000, 1002, 1004, 1006 and 1008, the corresponding resist is coated into a film with a thickness of about 25 nm to 27 nm, and the film is exposed to the E-beam radiation and then developed. In the curve 1000, the developed film show a high contrast due to a high SnO₂ content in the first photosensitive material represented by the formula (A). To achieve a desired contrast, in the curves 1002, 1004, and 1006, energy doses of the E-beam radiation required to expose the films are lower than an energy dose of the E-beam radiation required to expose the film in the curve 1000 and 1008.

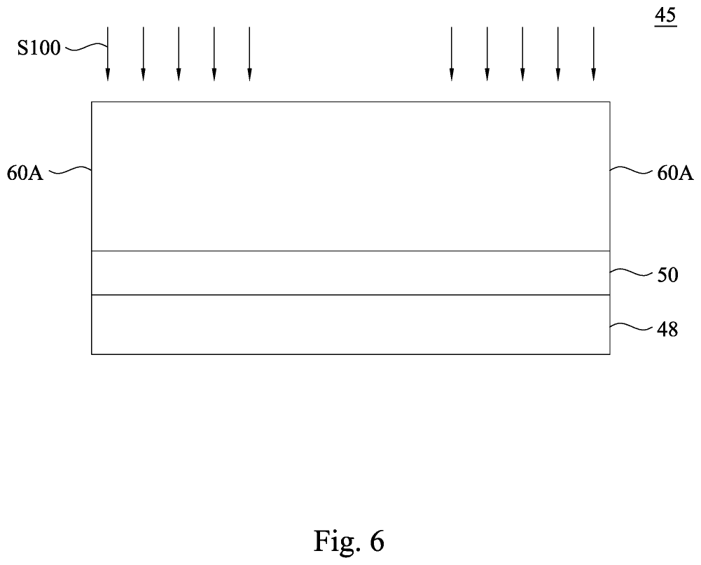

Reference is made to block S204 of FIG. 2 and to FIG. 6. An exposure process S100 is performed to the photoresist layer 60. In some embodiments, the photoresist layer 60 is exposed to an ultraviolet radiation. In some embodiments, the photoresist layer 60 is exposed to the EUV radiation using a dose of EUV radiation in a range from 30 mJ/cm² to 398 mJ/cm². After the photoresist layer 60 is exposed, the photoresist layer 60 is baked at 70° C. to 100° C., such as 80° C., for 60 seconds to 80 seconds, for example, 60 seconds.

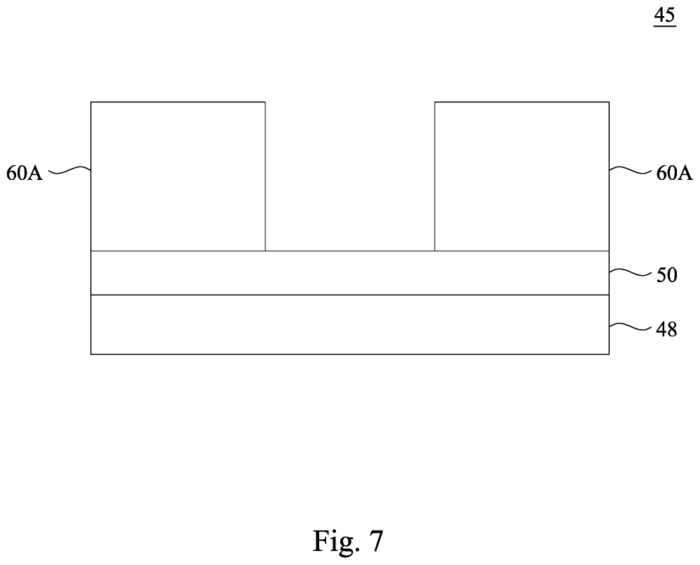

Reference is made to block S206 of FIG. 2 and to FIG. 7. The photoresist layer 60 is developed, forming patterned photoresists 60A separated by a recess. In some embodiments, the exposed photoresist layer 60 is developed using a developer for 50 to 70 seconds, such as 60 seconds. Due to the Sn—Cl bonds in the second, third and fourth photosensitive materials, the patterned photoresists 60A include a SnOₓCl_{y} structure instead of a SnO₂ structure. There are two types of developing processes: a positive tone development (PTD) process and a negative tone development (NTD) process. The PTD process uses a positive tone developer, which generally refers to a developer that selectively dissolves and removes exposed portions of the photoresist layer 60. The NTD process uses a negative tone developer, which generally refers to a developer that selectively dissolves and removes unexposed portions of the photoresist layer 60. In some embodiments, the PTD developers are aqueous base developers, such as tetraalkylammonium hydroxide (TMAH). In some embodiments, the NTD developers are organic-based developers, such as n-butyl acetate (n-BA) or acetone.

The patterned photoresists 60A exposed using low energy dose of EUV radiation can have a clear and well-defined line, edge and space. For example, the patterned photoresists 60A have an improved edge roughness (LWR) and an improved critical dimension uniformity (CDU). In some embodiments, the patterned photoresists 60A may have a uniform pitch and a uniform half-pinch (HP).

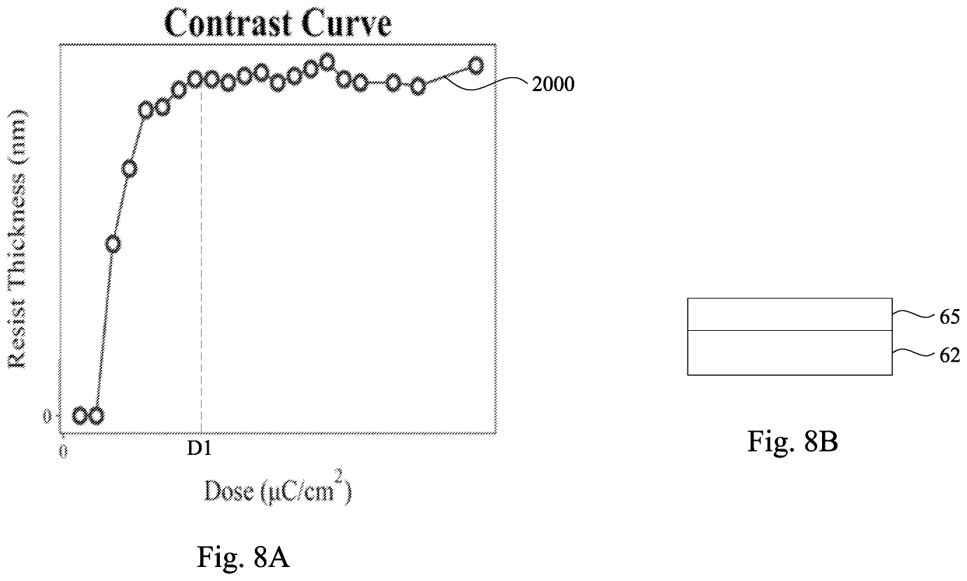

In some embodiments, the curable composition of the photoresist layer 60 may have a mixture (B-1). The mixture (B-1) includes the first photosensitive material represented by the formula (Ba) and the second photosensitive material represented by the formula (1a). A weight ratio of the first photosensitive material to the second photosensitive material is about 1.3:1. FIG. 8A is a diagram showing a contrast curve of a resist thickness versus a dose energy of an E-beam in accordance with some embodiments. In a curve 2000, the corresponding resist is coated into a film, and the film is exposed to the E-beam radiation and then developed. In the curve 2000, an energy dose D1 of the E-beam radiation required to expose the film is in a range from about 600 μC/cm² to about 650 μC/cm², such as about 640 μC/cm².

FIG. 8B shows a cross-sectional view of a photoresist layer over a substrate in accordance with some embodiments. Reference is made to FIG. 8B. In some embodiments, a mixture (B-2) is formed into a photoresist layer 65 on the substrate 62. The mixture (B-2) is similar to the mixture (B-1), except for the ratio of the first photosensitive material of the mixture (B-2) and the second photosensitive material of the mixture (B-2) is about 1:1. In some embodiments, the photoresist layer 65 is smooth over a large area. For example, the photoresist layer 65 may have a surface roughness (Rᵣₘₛ) of 0.55 nm to 0.65 nm, such as 0.60 nm, measured by means of the atomic force microscope (AFM).

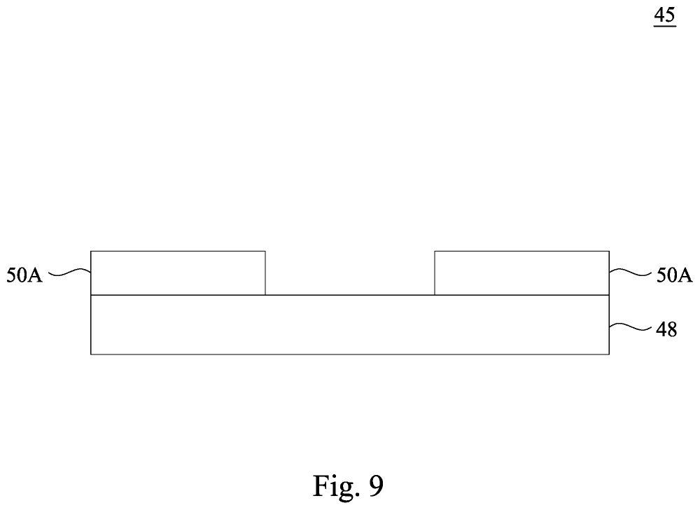

Using the patterned photoresists 60A (see FIG. 7) as a mask, additional fabrication processes such as etching or implantation may be performed. Reference is made to block S208 of FIG. 2 and to FIG. 9. For example, the material layer 50 is etched into patterned material layers 50A separated by a recess. Thereafter, the patterned photoresists 60A may be removed by a photoresist removal process known in the art, such as a stripping or an ashing process.

Although the discussions above use EUV lithography as an example, it is understood that the various aspects of the photoresist layer may apply to other types of lithography as well, such as an e-beam lithography.

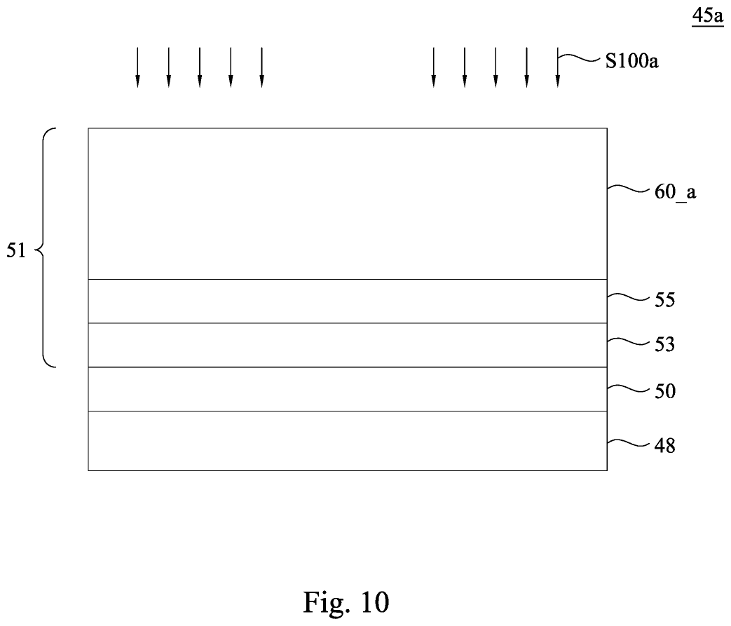

FIG. 10 illustrates a fragmentary cross-sectional side view of a semiconductor device 45a in accordance with some other embodiments of the present disclosure. Reference is made to FIG. 10. In some other embodiments, a tri-layer resist stack 51 is formed over the material layer 50. The tri-layer resist stack 51 includes a bottom layer 53, a middle layer 55 and a top layer 60_a. In some embodiments, the bottom layer 53, the middle layer 55, and the top layer 60_a are formed over the substrate 48 in sequence.

In the present example, the bottom layer 53 is a carbon-rich layer while the middle layer 55 is a silicon-rich layer designed to provide an etch selectivity between those two layers. The top layer 60_a has a composition same as the composition of the photoresist layer 60, as discussed previously with regard to FIG. 3. In the tri-layer resist stack 51, the photo-sensitive and etch-resistance functions of the photoresist are spread to those three layers, thus the top layer 60_a can be designed differently to enhance imaging resolution and lithography patterning quality.

In some embodiments, the bottom layer 53 is carbon-containing polymeric material formed on the substrate 48 by a proper technique, such as spin-on coating. Thus coated bottom layer 53 may be further cured, such as by baking. Exemplary materials for the bottom layer 53 include a carbon backbone polymer. In an embodiment, the bottom layer 53 is omitted.

The middle layer 55 is a silicon-rich material layer deposited on the bottom layer 53 by a proper technique, such as spin-on coating. The middle layer 55 may include a silicon-containing inorganic polymer. In a further embodiment, the middle layer includes a siloxane polymer (e.g., a polymer having a backbone of O—Si—O—Si— etc.). The middle layer 55 is designed to have a composition different from the bottom layer 53 in order to have enough etch selectivity between those two layers. In some embodiments, the middle layer 55 is designed to reduce the carbon concentration such that the silicon concentration of the middle layer 55 is relatively increased.

An exposure process S100a is performed to the top layer 60_a. The exposure process S100a is similar to the exposure process S100 as discussed previously with regard to FIG. 6, and thus the description thereof is omitted.

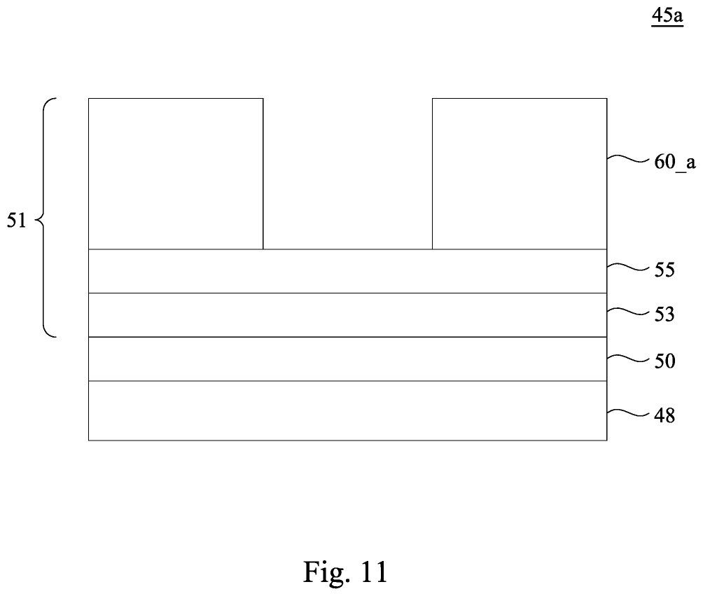

Reference is made to FIG. 11. The top layer 60_a of the tri-layer resist stack 51 is developed. For example, subsequent lithography processes (e.g., post-exposure baking, developing, rinsing, etc.) may be performed to form the patterned top layer 60_a. As discussed above, the patterned top layer 60_a exposed using low energy dose of EUV radiation can have a clear and well-defined line, edge and space. For example, the top layer 60_a has an improved edge roughness (LWR) and an improved critical dimension uniformity (CDU).

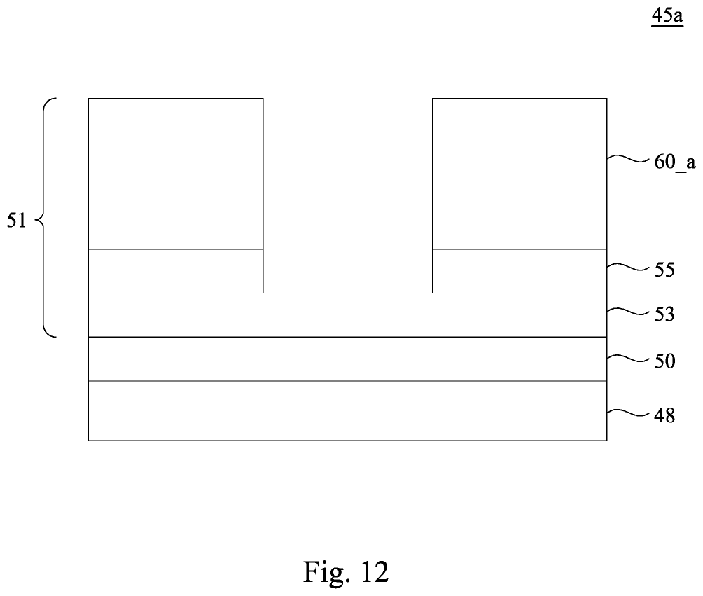

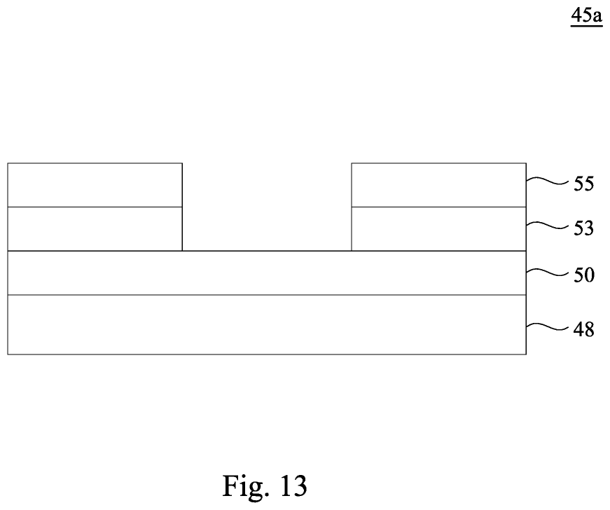

Reference is made to FIG. 12. The first etching process is performed to the middle layer 55 using the patterned top layer 60_a as an etch mask, thereby transforming the circuit pattern from the top layer 60_a to the middle layer 55, thus forming the patterned middle layer 55. The first etching process is designed with an etchant to selectively etch the middle layer 55 but stops on the bottom layer 53. The first etching process may be a dry etch, a wet etch or a combination thereof. After the first etching process, the top layer 60_a is removed by wet stripping or plasma ashing, as illustrated in FIG. 13.

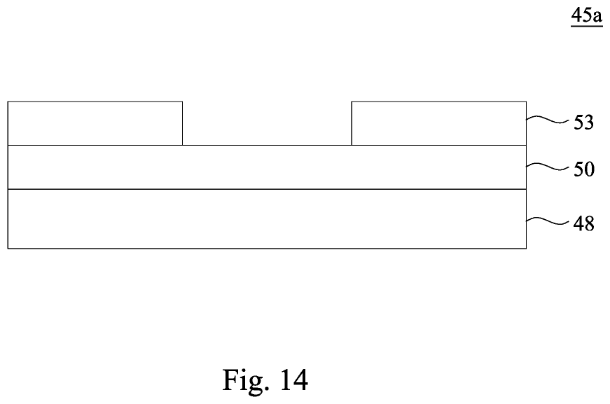

Reference is made to FIG. 13. A second etching process is performed to the bottom layer 53 using the patterned middle layer 55 as an etch mask, thereby transforming the circuit pattern from the patterned middle layer 55 to the bottom layer 53, forming the patterned bottom layer 53. The second etching process is designed with an etchant to selectively etch the bottom layer 53 without significantly removal of the patterned middle layer 55 due to the etching selectivity between the middle layer 55 and the bottom layer 53. The second etching process may be a dry etch, a wet etch or a combination thereof. After the second etching process, the patterned middle layer 55 may be removed by a proper technique, such as wet etching. The resulting structure is shown in FIG. 14.

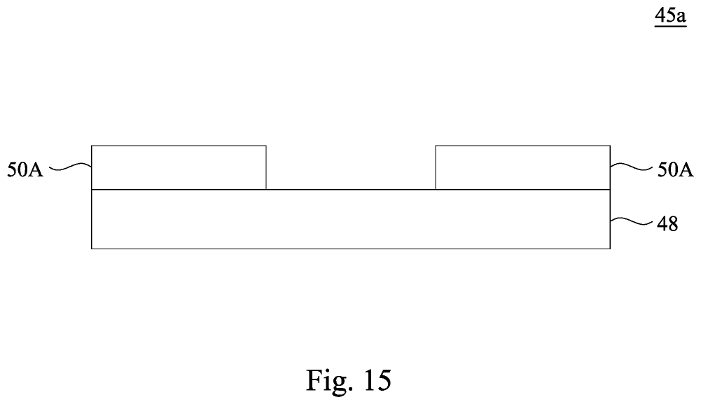

Reference is made to FIG. 15. Using the patterned bottom layer 53 (see FIG. 14) as a mask, additional fabrication processes such as etching or implantation may be performed. For example, the material layer 50 is etched into patterned material layers 50A separated by a recess. Thereafter, the patterned bottom layer 53 may be removed by a suitable removing process.

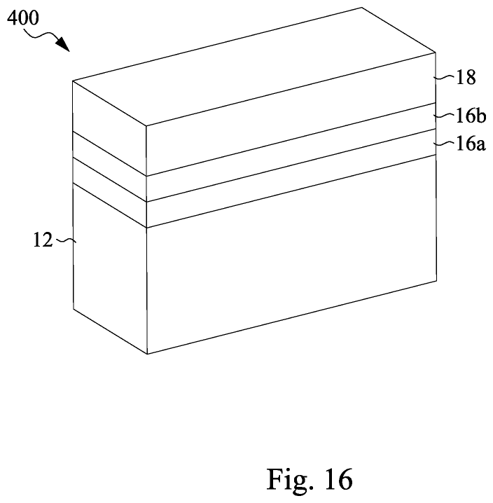

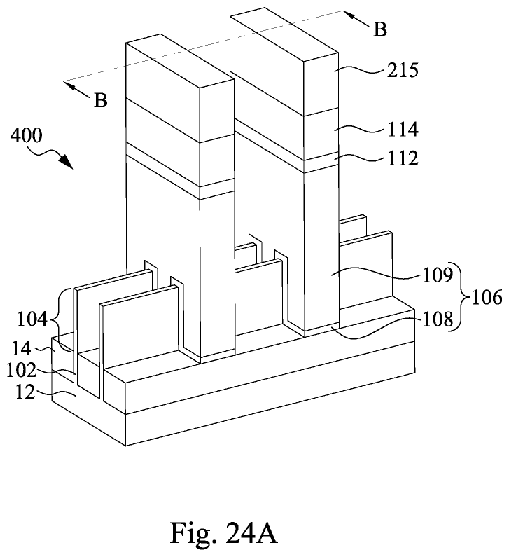

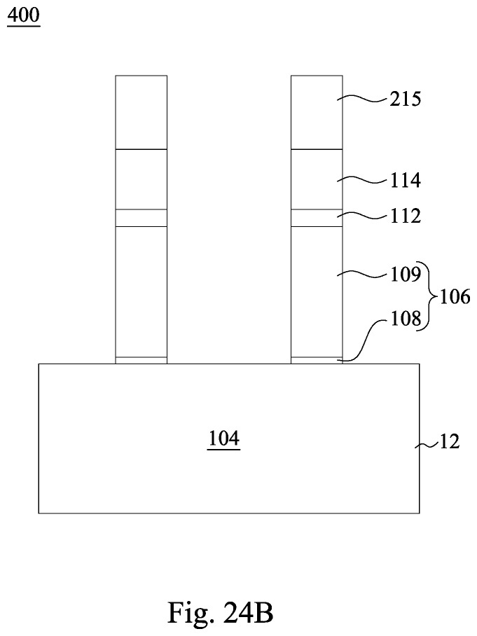

FIGS. 16, 17, 18, 19, 20, 21, 22, 23 and 24A illustrate perspective views of additional fabrication processes in the formation of a semiconductor device 400 in accordance with some embodiments of the present disclosure. FIGS. 24B, 25, 26 and 27 illustrate cross-sectional views of additional fabrication processes in the formation of a semiconductor device 400 in accordance with some embodiments of the present disclosure. Reference is made to FIG. 16. FIG. 16 illustrates a perspective view of an initial structure. The initial structure includes a substrate 12, which is a part of a semiconductor wafer. The substrate 12 is similar to the substrate 48 as discussed previously with regard to FIG. 3 in terms of composition, and its detailed description will be omitted herein. A pad layer 16a and a mask layer 16b are formed on the substrate 12. The pad layer 16a may be a thin film including silicon oxide formed, for example, using a thermal oxidation process. The pad layer 16a may act as an adhesion layer between the substrate 12 and the mask layer 16b. In some embodiments, the mask layer 16b is formed of silicon nitride, for example, using low-pressure chemical vapor deposition (LPCVD). In other embodiments, the mask layer 16b is formed by thermal nitridation of silicon, plasma enhanced chemical vapor deposition (PECVD), or plasma anodic nitridation. The mask layer 16b is used as a hard mask during a subsequent photolithography process. A photoresist layer 18 may be formed on the mask layer 16b using a spin coating method. The photoresist layer 18 is similar to the photoresist layer 60 as discussed previously with regard to FIG. 3 in terms of composition and formation method, and its detailed description will be omitted herein. For example, the photoresist layer 18 is patterned using an EUV radiation at a low energy dose.

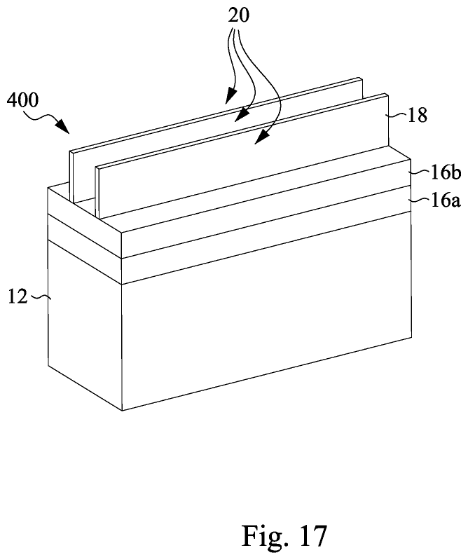

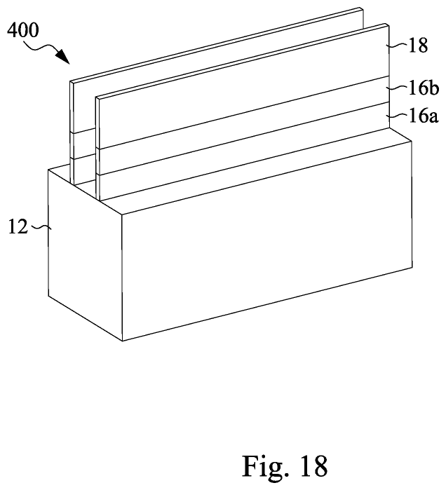

Referring to FIG. 17, the photoresist layer 18 is patterned, forming openings 20 in the photoresist layer 18. The mask layer 16b is thus exposed by the openings 20. Referring to FIG. 18, the mask layer 16b and the pad layer 16a are etched through the openings 20, exposing the underlying substrate 12.

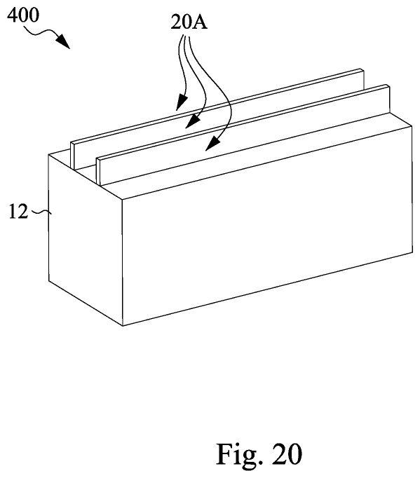

In some other embodiments, the photoresist layer 18A is formed on the substrate 12 without forming the pad layer 16a and the mask layer 16b (see FIG. 16) prior to forming the photoresist layer 18A. That is, the photoresist layer 18A is in contact with the substrate 12. Referring to FIG. 20, the photoresist layer 18A is then patterned, forming openings 20A in the photoresist layer 18A. In some other embodiments, the substrate 12 etched by a tri-layer resist, for example, the tri-layer formed by a bottom layer, a middle layer and a top layer as discussed previously with regard to FIGS. 10-15, in which the top layer is made of the composition substantially the same as the composition of the photoresist layer 18.

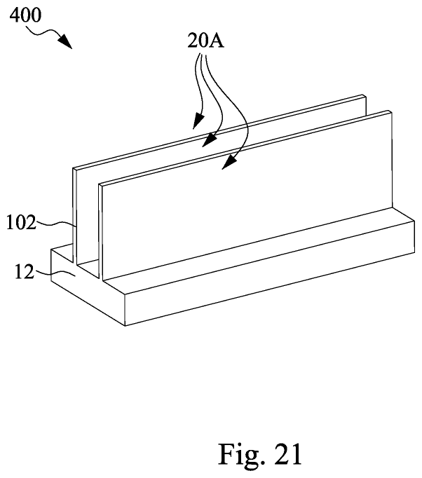

Referring to FIG. 21, the exposed substrate 12 is then etched, forming trenches 22. Portions of the substrate 12 between neighboring trenches 22 form semiconductor strips 102. The trenches 22 may be strips (when viewed from a top of the substrate 12) that are parallel to each other, and closely located from each other. After etching the substrate 12, the photoresist layer 18 is removed. Next, a cleaning step may be performed to remove native oxide formed on surfaces of the substrate 12. The cleaning may be performed using diluted hydrofluoric (HF) acid, for example.

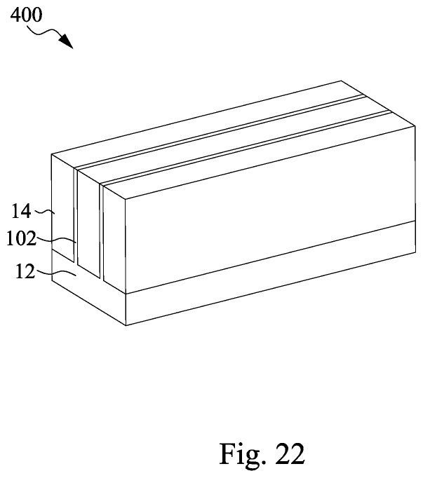

Next, the trenches 22 are filled with a dielectric material using a spin-on method, flowable chemical vapor deposition (FCVD), or the like. In some embodiments, a dielectric liner (not shown) is formed in the trenches 22 prior to forming the dielectric material and may be a conformal layer formed using a deposition technique such as atomic layer deposition (ALD) or the like. A planarization such as chemical mechanical polish (CMP) is then performed to the dielectric material, as shown in FIG. 22, and hence shallow trench isolation (STI) region 14 is formed. In some embodiments, during the planarization, the mask layer 16b and the pad layer 16a, if exist, are removed.

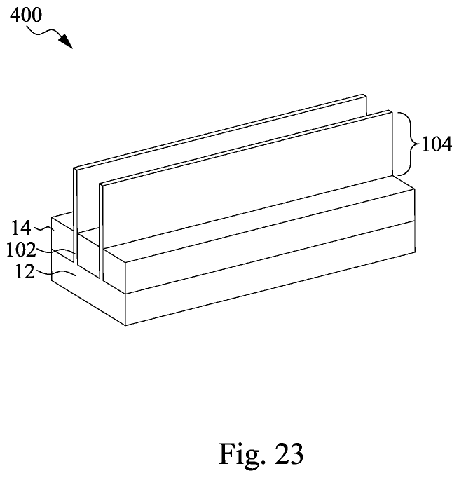

Referring to FIG. 23, the STI regions 14 are recessed, so that top portions of semiconductor strips 102 protrude higher than top surfaces of the neighboring STI regions 14 to form protruding fins 104. The etching may be performed using a dry etching process or a wet etching process.

Referring to FIGS. 24A and 24B, dummy gate structures 106 are formed on the top surfaces and the sidewalls of fins 104. FIG. 24B illustrates a cross-sectional view obtained from a vertical plane containing line B-B in FIG. 24A. Formation of the dummy gate structures 106 includes depositing in sequence a blankly formed gate dielectric layer and a blankly formed dummy gate electrode layer across the fins 104, followed by patterning the blanket formed gate dielectric layer and the blankly formed dummy gate electrode layer. As a result of the patterning, the dummy gate structure 106 includes a dummy gate dielectric layer 108 and a dummy gate electrode 109 over the dummy gate dielectric layer 108. The dummy gate dielectric layers 108 can be any acceptable dielectric layer, such as silicon oxide, silicon nitride, the like, or a combination thereof, and may be formed using any acceptable process, such as thermal oxidation, a spin process, CVD, or the like. The dummy gate electrodes 109 can be any acceptable electrode layer, such as comprising polysilicon, metal, the like, or a combination thereof. The gate electrode layer can be deposited by any acceptable deposition process, such as CVD, plasma enhanced CVD (PECVD), or the like. Each of dummy gate structures 106 crosses over a single one or a plurality of fins 104. The dummy gate structures 106 may have lengthwise directions perpendicular to the lengthwise directions of the respective fins 104.

The blankly formed dummy gate electrode layer and the blankly formed gate dielectric layer may be patterned using a tri-layer structure. Bottom masks 112, top masks 114 and photoresist layers 215 are formed over the blankly formed dummy gate electrode layer in sequence. The photoresist layers 215 may be similar to the patterned photoresist 60A in terms of composition and formation methods as discussed previously with regard to FIGS. 3, 6 and 7, and its detailed description will be omitted herein.

In an alternative embodiment, the bottom masks 112 and the top masks 114 are made of one or more layers of SiO₂, SiCN, SiON, Al₂O₃, SiN, or other suitable materials. In certain embodiments, the bottom masks 112 include silicon nitride, and the top masks 114 include silicon oxide.

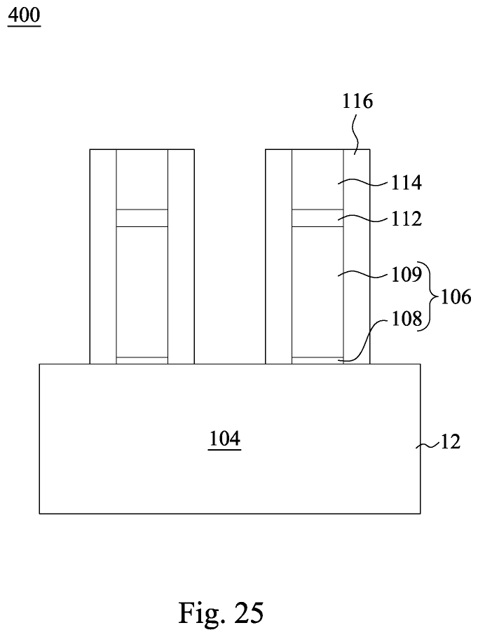

Next, as illustrated in FIG. 25, gate spacers 116 are formed on sidewalls of the dummy gate structures 106. In some embodiments of the gate spacer formation step, a spacer material layer is deposited on the substrate 12. The spacer material layer may be a conformal layer that is subsequently etched back to form gate spacers 116. The spacer material layer is made of a low-k dielectric material. The low-k dielectric material has a dielectric constant (k value) of lower than about 3.5. Suitable materials for the low-k dielectric material may include silicon oxide, silicon nitride, silicon oxynitride, or the like. By way of example and not limitation, the spacer material layer may be formed using processes such as, CVD process, a subatmospheric CVD (SACVD) process, a flowable CVD process, an ALD process, a physical vapor deposition (PVD) process, or other suitable process. An anisotropic etching process is then performed on the deposited spacer material layer to expose portions of the fins 104 not covered by the dummy gate structures 106 (e.g., in source/drain regions of the fins 104). Portions of the spacer material layer directly above the dummy gate structures 106 may be completely removed by this anisotropic etching process. Portions of the spacer material layer on sidewalls of the dummy gate structures 106 may remain, forming gate spacers, which are denoted as the gate spacers 116, for the sake of simplicity. In some embodiments, the gate spacers 116 may be used to offset subsequently formed doped regions, such as source/drain regions. The gate spacers 116 may further be used for designing or modifying the source/drain region profile.

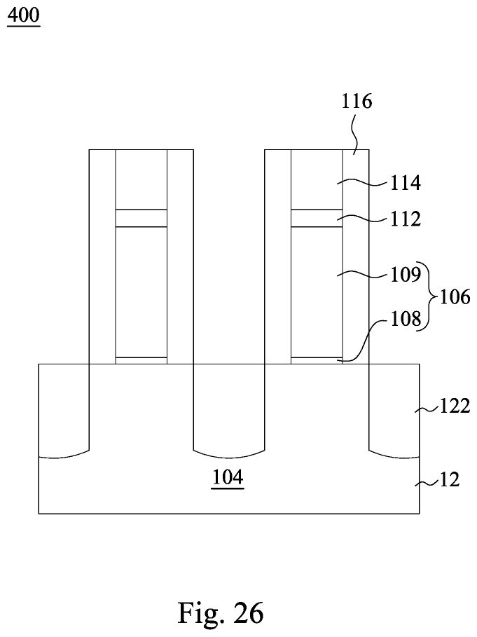

In FIG. 26, after formation of the gate spacers 116 is completed, source/drain epitaxial structures 122 are formed on source/drain regions of the protruding fins 104 that are not covered by the dummy gate structures 106 and the gate spacers 116. In some embodiments, formation of the source/drain epitaxial structures 122 includes recessing source/drain regions of the fin 104, followed by epitaxially growing semiconductor materials in the recessed source/drain regions of the fin 104. The source/drain epitaxial structures 122 are on opposite sides of the dummy gate structure 106.

The source/drain regions of the fins 104 can be recessed using suitable selective etching processing that attacks the fins 104, but hardly attacks the gate spacers 116 and the top masks 114 of the dummy gate structures 106. For example, recessing the fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the protruding fins 104 at a faster etch rate than it etches the gate spacers 116 and the top masks 114 of the dummy gate structures 106. In some other embodiments, recessing the protruding fins 104 may be performed by a wet chemical etch which etches the fins 104 at a faster etch rate than it etches the gate spacers 116 and the top masks 114 of the dummy gate structures 106. In some other embodiments, recessing the protruding fins 104 may be performed by a combination of a dry chemical etch and a wet chemical etch.

Once recesses are created in the source/drain regions of the fin 104, source/drain epitaxial structures 122 are formed in the source/drain recesses in the fin 104 by using one or more epitaxy or epitaxial (epi) processes that provides one or more epitaxial materials on the protruding fins 104. During the epitaxial growth process, the gate spacers 116 limit the one or more epitaxial materials to source/drain regions in the fin 104. In some embodiments, the lattice constants of the source/drain epitaxial structures 122 are different from the lattice constant of the fins 104, so that the channel region in the fin 104 and between the source/drain epitaxial structures 122 can be strained or stressed by the source/drain epitaxial structures 122 to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the fins 104.

In some embodiments, the source/drain epitaxial structures 122 may include Ge, Si, GaAs, AlGaAs, SiGe, GaAsP, SiP, or other suitable material. The source/drain epitaxial structures 122 may be in-situ doped during the epitaxial process by introducing doping species including p-type dopants, such as boron or BF2, n-type dopants, such as phosphorus or arsenic, and/or other suitable dopants including combinations thereof. If the source/drain epitaxial structures 122 are not in-situ doped, an implantation process (i.e., a junction implant process) is performed to dope the source/drain epitaxial structures 122. In some exemplary embodiments, the source/drain epitaxial structures 122 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain epitaxial structures 122 are formed, an annealing process can be performed to activate the p-type dopants or n-type dopants in the source/drain epitaxial structures 122. The annealing process may be, for example, a rapid thermal anneal (RTA), a laser anneal, a millisecond thermal annealing (MSA) process or the like.

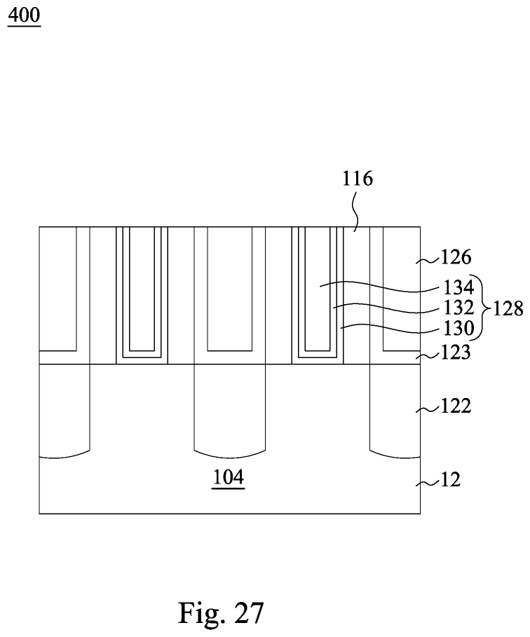

Next, in FIG. 27, a contact etch stop layer (CESL) 123 and an interlayer dielectric (ILD) layer 126 are formed on the substrate 12 in sequence. In some examples, the CESL 123 includes a silicon nitride layer, silicon oxide layer, a silicon oxynitride layer, and/or other suitable materials having a different etch selectivity than the ILD layer 126. The CESL 123 may be formed by plasma-enhanced chemical vapor deposition (PECVD) process and/or other suitable deposition or oxidation processes. In some embodiments, the ILD layer 126 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 123. The ILD layer 126 may be deposited by a PECVD process or other suitable deposition technique. In some embodiments, after formation of the ILD layer 126, the wafer may be subject to a high thermal budget process to anneal the ILD layer 126.

In some examples, after forming the ILD layer 126, a planarization process may be performed to remove excessive materials of the ILD layer 126 and the CESL 123. For example, a planarization process includes a chemical mechanical planarization (CMP) process which removes portions of the ILD layer 126 and the CESL 123 overlying the dummy gate structures 106. In some embodiments, the CMP process also removes bottom masks 112 and top masks 114 (as shown in FIG. 16) and exposes the dummy gate electrodes 109.

An etching process is performed to remove the dummy gate electrode 109 and the dummy gate dielectric layer 108, resulting in gate trenches between corresponding gate spacers 116. The dummy gate structures 106 are removed using a selective etching process (e.g., selective dry etching, selective wet etching, or a combination thereof) that etches materials in the dummy gate structures 106 at a faster etch rate than it etches other materials (e.g., gate spacers 116 and/or the ILD layer 126).

Thereafter, replacement gate structures 128 are respectively formed in the gate trenches. The gate structures 128 may be the final gates of FinFETs. In FinFETs, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. The final gate structures each may be a high-k/metal gate (HKMG) stack, however other compositions are possible. In some embodiments, each of the gate structures 128 forms the gate associated with the three-sides of the channel region provided by the fin 104. Stated another way, each of the gate structures 128 wraps around the fin 104 on three sides. In various embodiments, the high-k/metal gate structure 128 includes a gate dielectric layer 130 lining the gate trench, a work function metal layer 132 formed over the gate dielectric layer 130, and a fill metal 134 formed over the work function metal layer 132 and filling a remainder of gate trenches. The gate dielectric layer 130 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (˜3.9). The work function metal layer 132 and/or the fill metal 134 used within high-k/metal gate structures 128 may include a metal, metal alloy, or metal silicide. Formation of the high-k/metal gate structures 128 may include multiple deposition processes to form various gate materials, one or more liner layers, and one or more CMP processes to remove excessive gate materials.

In some embodiments, the interfacial layer of the gate dielectric layer 130 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 130 may include hafnium oxide (HfO₂). Alternatively, the gate dielectric layer 130 may include other high-k dielectrics, such as hafnium silicon oxide (HfSiO), hafnium silicon oxynitride (HfSiON), hafnium tantalum oxide (HMO), hafnium titanium oxide (HfSiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 132 may include work function metals to provide a suitable work function for the high-k/metal gate structures 128. For an n-type FinFET, the work function metal layer 132 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 132 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal 134 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, the semiconductor device 400 includes other layers or features not specifically illustrated. In some embodiments, back end of line (BEOL) processes are performed on the semiconductor device 400. In some embodiments, the semiconductor device 400 is formed by a non-replacement metal gate process or a gate-first process.

Based on the above discussions, it can be seen that the present disclosure offers advantages over conventional methods. It is understood, however, that other embodiments may offer additional advantages, and not all advantages are necessarily disclosed herein, and that no particular advantage is required for all embodiments. One advantage is that mixture of the curable composition of the photoresist layer is stable with air without formulation. Another advantage is that a costly formulation to remove water residues is not required. Yet another advantage is that strict operations to exclude air and/or moisture are not required either. Yet another advantage is that a low energy dose of EUV radiation to expose the photoresist layer is required due to the Sn-vinyl units in the second photosensitive material, the Sn-vinyl units in the third photosensitive material or the Sn-allyl units in the fourth photosensitive material, which provides high photosensitivity.

In some embodiments, a photoresist composition including a mixture. The mixture includes a first photosensitive material and a second photosensitive material different from the first photosensitive material. The first photosensitive material is a 6-Sn oxide cluster, a 12-Sn oxide cluster or a combination thereof. In some embodiments, the second photosensitive material is represented by formula (1):

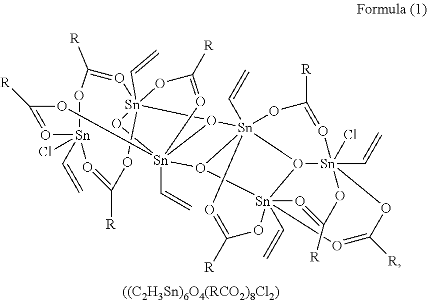

and in the formula (1), R is represented by one of formulae (I-1) to (I-7):

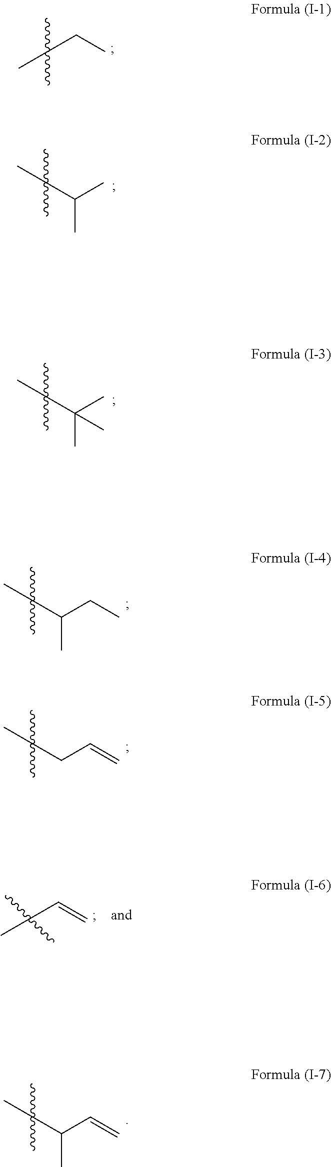

In some embodiments, the photoresist composition further includes a third photosensitive material, wherein the third photosensitive material is represented by formula (2):

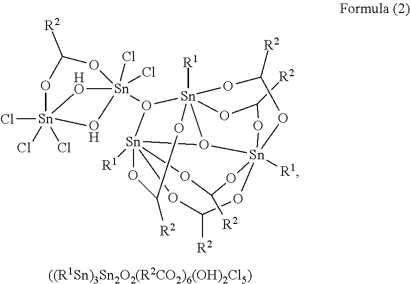

in the formula (2), R¹ is represented by formula (L-1):

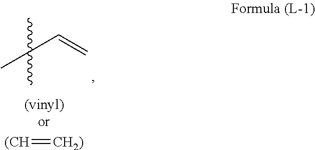

and in the formula (2), R² is represented by one of formulae (K-1) to (K-6):

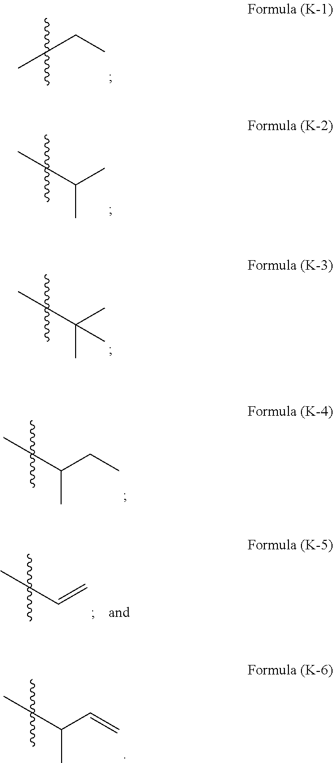

In some embodiments, the photoresist composition further includes a fourth photosensitive material, wherein the fourth photosensitive material is represented by formula (3):

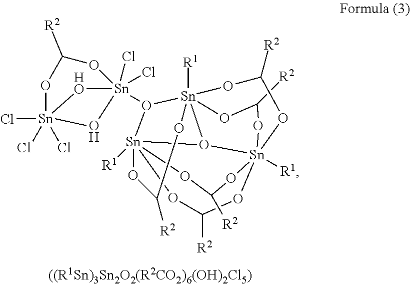

in the formula (3), R¹ is represented by formula (L-2):

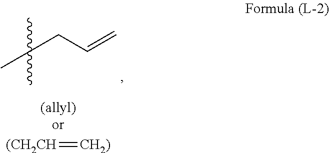

and in the formula (3), R² is represented by one of formulae (K-1) to (K-6):

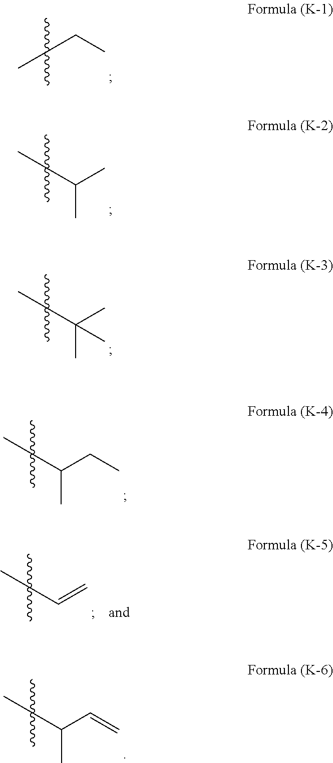

In some embodiments, an amount of the first photosensitive material in the mixture is greater than an amount of the second photosensitive material in the mixture. In some embodiments, a weight percentage of the first photosensitive material in the mixture is in a range from 60% to 70%. In some embodiments, a weight percentage of the second photosensitive material in the mixture is in a range from 30% to 40%. In some embodiments, the first photosensitive material is represented by formula (A):

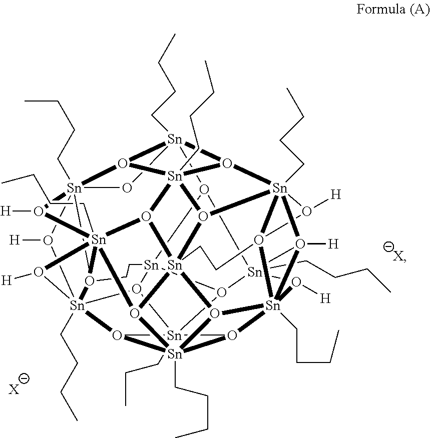

in the formula (A), X represents OH, Cl, Br, BF₄, 0.5C₂O₄, or RCO₂, and in the RCO₂, R has 1 to 15 carbon atoms. In some embodiments, the first photosensitive material is represented by formula (B):

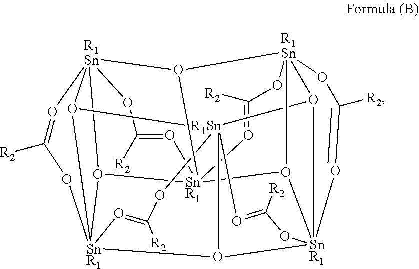

in the formula (B), R₁ represents —CH₃ or is represented by one of formulae (M-1) to (M-3):

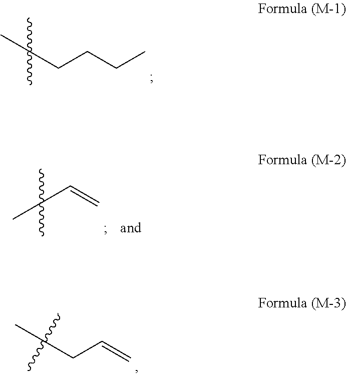

and in the formula (B), R₂ is represented by one of formulae (M-4) to (M-10):

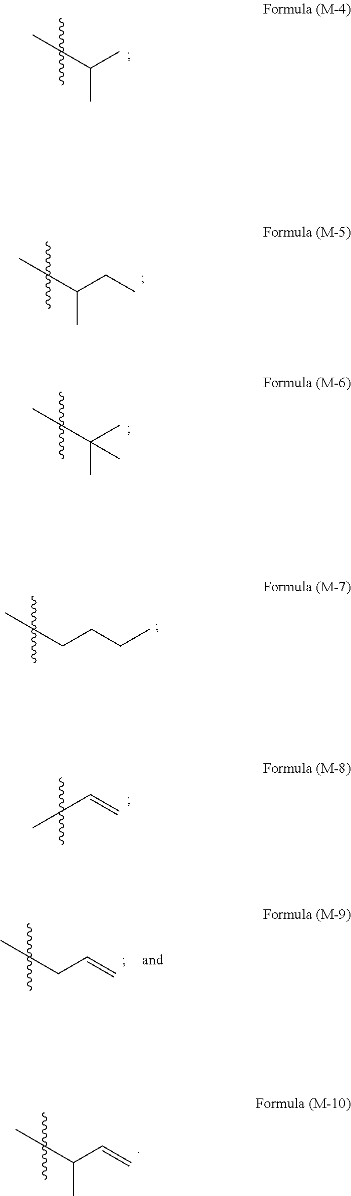

In some embodiments, the second photosensitive material has a structure being more irregular than a structure of the first photosensitive material.

In some embodiments, a method of forming a photoresist composition includes the following steps. A first photosensitive material and a second photosensitive material different from the first photosensitive material are mixed to form a curable composition. The second photosensitive material is a 6Sn(vinyl)-2Cl cluster, a 5Sn-5Cl cluster, or a combination thereof. The first photosensitive material is represented by formula (A) or formula (B):

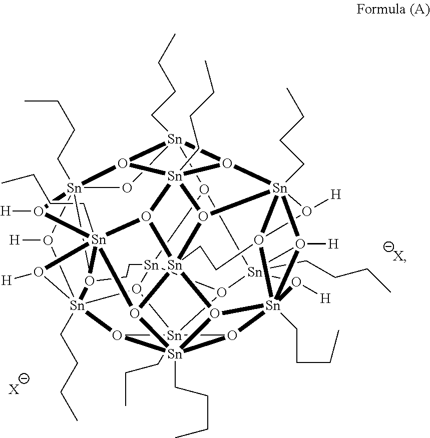

in the formula (A), X represents OH, Cl, Br, BF₄, 0.5C₂O₄, or RCO₂, and in the RCO₂, R has 1 to 15 carbon atoms,

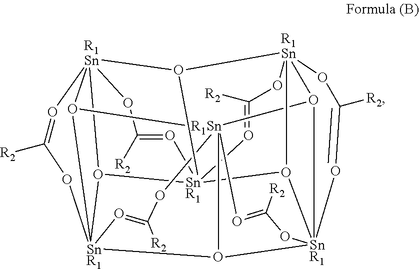

in the formula (B), R₁ represents —CH₃ or is represented by one of formulae (M-1) to (M-3):

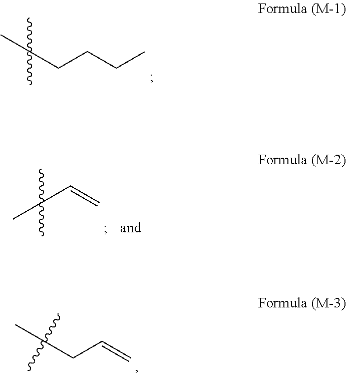

and in the formula (B), R₂ is represented by one of formulae (M-4) to (M-10):

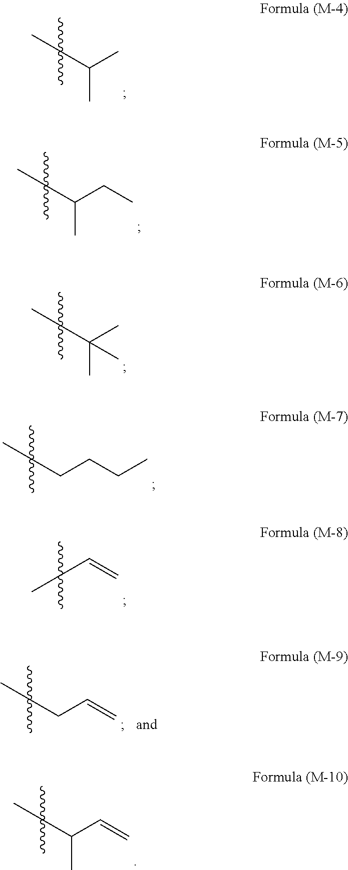

The curable composition is dissolved in a first solvent. In some embodiments, the 6Sn(vinyl)-2Cl cluster is formed by reacting a first compound of formula (C-1):

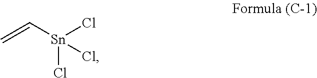

with a second compound of formula (C-2):

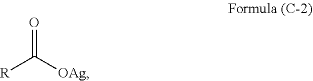

in the formula (C-2), R is represented by one of formulae (I-1) to (I-7):

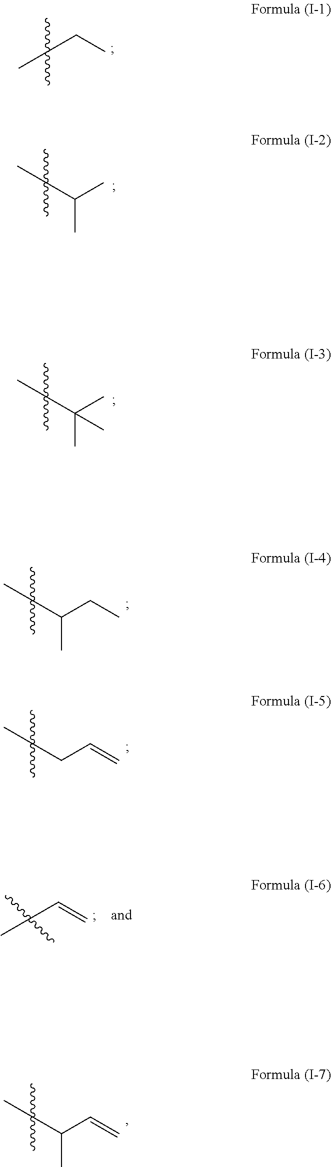

in a second solvent. In some embodiments, the 5Sn-5Cl cluster is formed by: (2-1) reacting a first compound of formula (C-3):

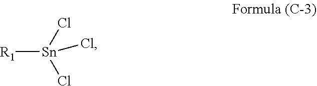

in the formula (C-3), R₁ is represented by formula (L-1):

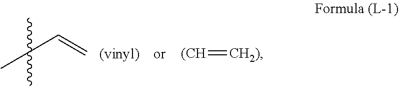

with a second compound of formula (C-4):

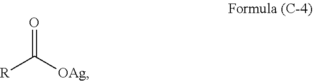

in the formula (C-4), R₂ is represented by one of formulae (K-1) to (K-6):

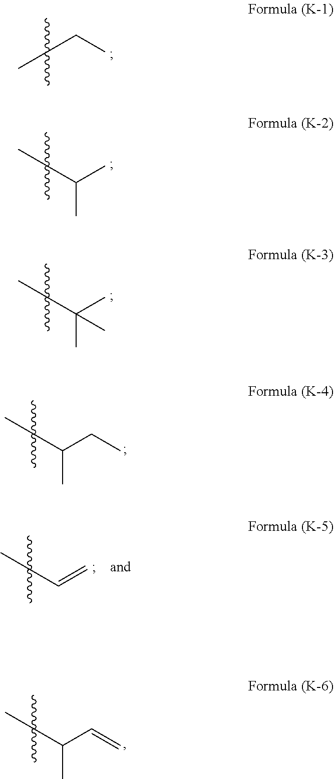

in a second solvent to obtain a substance, and (2-2) recrystallizing the substance. In some embodiments, the 5Sn-5Cl cluster is formed by: (2-1′) reacting a first compound of formula (C-3′):

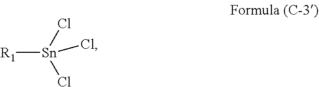

in the formula (C-3′), R₁ is represented by formula (L-2):

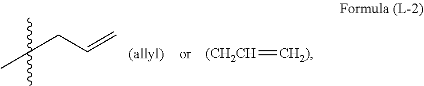

with a second compound of formula (C-4′):

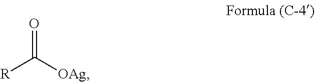

in the formula (C-4′), R₂ is represented by one of formulae (K-1) to (K-6):

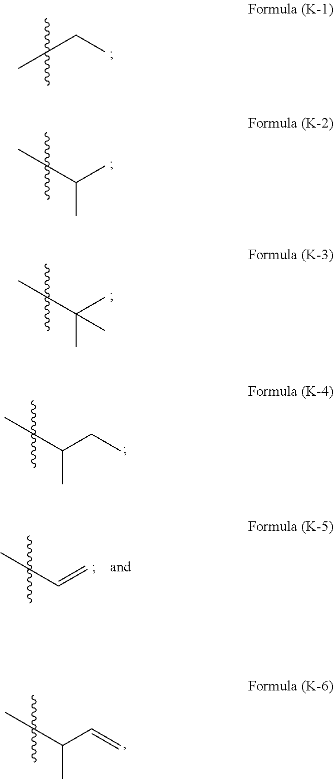

in a second solvent to obtain a substance, and (2-2′) recrystallizing the substance.

In some embodiments, an extreme ultraviolet lithography (EUVL) method includes the following steps. A droplet generator is turned on to eject a metal droplet toward a zone of excitation in front of a collector. A laser source is turned on to emit a laser toward the zone of excitation, such that the metal droplet is heated by the laser to generate EUV radiation. The EUV radiation is guided, by using one or more first optics, toward a reflective mask in an exposure device. The EUV radiation is guided, by using one or more second optics, reflected from the reflective mask toward a photoresist coated substrate in the exposure device. The photoresist has a composition including a mixture including a first photosensitive material and a second photosensitive material. The first photosensitive material includes a 6-Sn oxide cluster, a 12-Sn oxide cluster, or a combination thereof. The second photosensitive material includes a 6Sn-2Cl cluster, a 5Sn-5Cl cluster, or a combination thereof. In some embodiments, a weight percentage of the first photosensitive material in the mixture is in a range from 60% to 70%. In some embodiments, a weight percentage of the second photosensitive material in the mixture is in a range from 30% to 40%. In some embodiments, the second photosensitive material has a Sn-allyl unit or a Sn-vinyl unit. In some embodiments, the second photosensitive material is represented by formula (2):

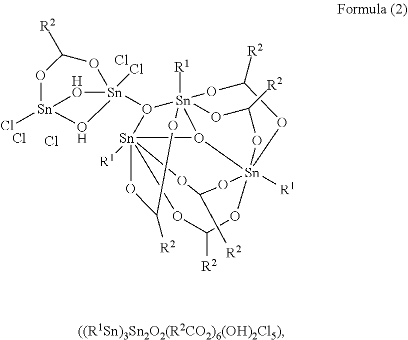

in the formula (2), R¹ is represented by formula (L-1):

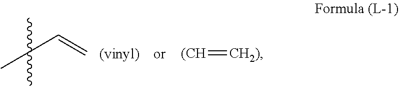

and in the formula (2), R² is represented by one of formulae (K-1) to (K-6):

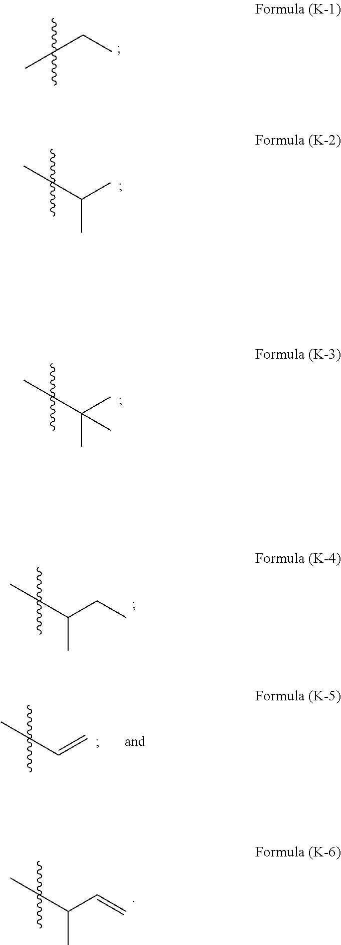

In some embodiments, the second photosensitive material is represented by formula (3):

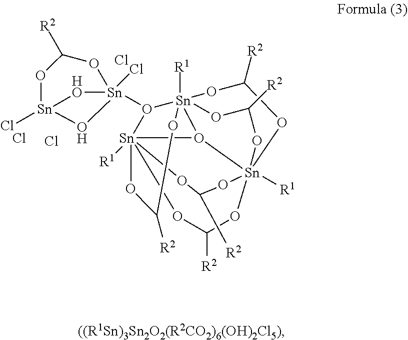

in the formula (3), R¹ is represented by formula (L-2):

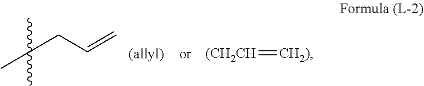

and in the formula (3), R² is represented by one of formulae (K-1) to (K-6):

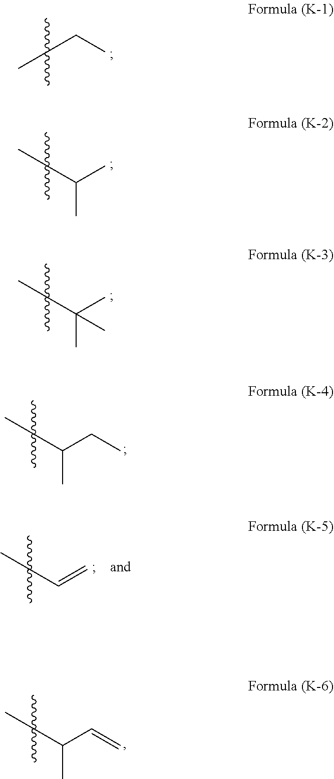

The foregoing outlines features of several embodiments or examples so that those skilled in the art may better understand the aspects of the present disclosure. Those skilled in the art should appreciate that they may readily use the prese0nt disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A photoresist composition, comprising:
a mixture, wherein the mixture comprises:
a first photosensitive material, wherein the first photosensitive material is a 6-Sn oxide cluster, a 12-Sn oxide cluster or a combination thereof; and
a second photosensitive material different from the first photosensitive material.

2. The photoresist composition of claim 1, wherein the second photosensitive material is represented by formula (1): 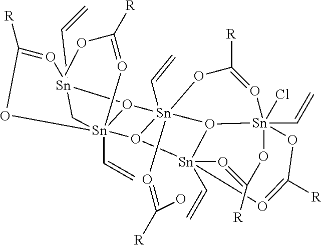
and in the formula (1), R is represented by one of formulae (I-1) to (I-7):

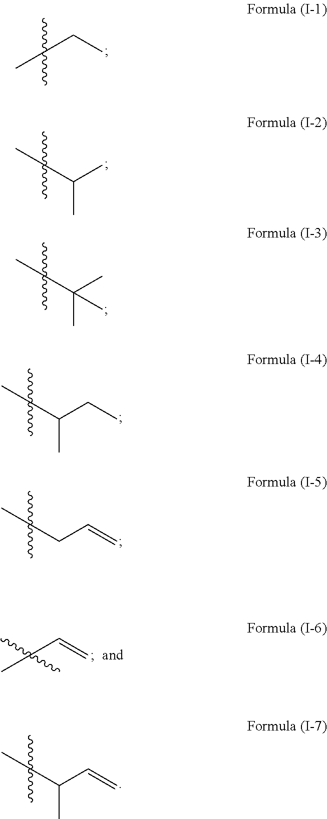

3. The photoresist composition of claim 1, further comprising:
a third photosensitive material, wherein the third photosensitive material is represented by formula (2): 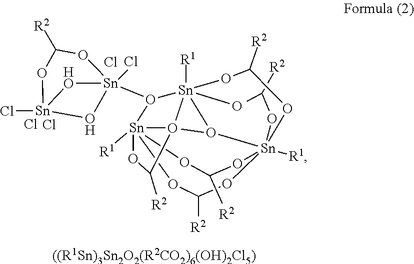
in the formula (2), R¹ is represented by formula (L-1): 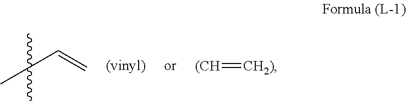
and in the formula (2), R² is represented by one of formulae (K-1) to (K-6):

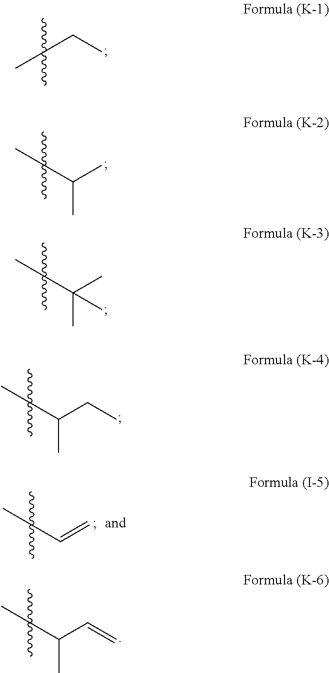

4. The photoresist composition of claim 1, further comprising:
a fourth photosensitive material, wherein the fourth photosensitive material is represented by formula (3): 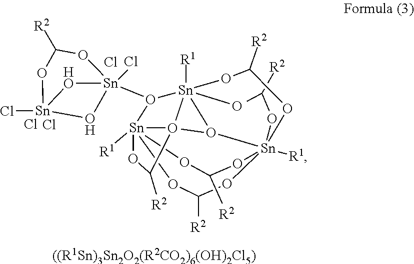
in the formula (3), R¹ is represented by formula (L-2): 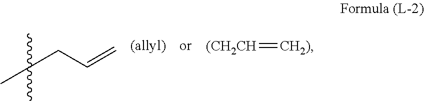
and in the formula (3), R² is represented by one of formulae (K-1) to (K-6):

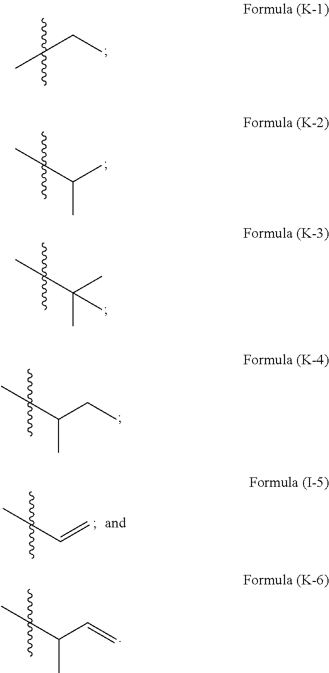

5. The photoresist composition of claim 1, wherein an amount of the first photosensitive material in the mixture is greater than an amount of the second photosensitive material in the mixture.

6. The photoresist composition of claim 1, wherein a weight percentage of the first photosensitive material in the mixture is in a range from 60% to 70%.

7. The photoresist composition of claim 1, wherein a weight percentage of the second photosensitive material in the mixture is in a range from 30% to 40%.

8. The photoresist composition of claim 1, wherein the first photosensitive material is represented by formula (A): 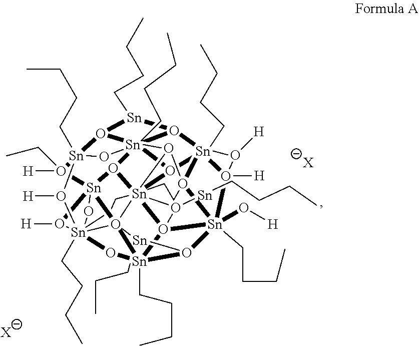
in the formula (A), X represents OH, Cl, Br, BF₄, 0.5C₂O₄, or RCO₂, and in the RCO₂, R has 1 to 15 carbon atoms.

9. The photoresist composition of claim 1, wherein the first photosensitive material is represented by formula (B): 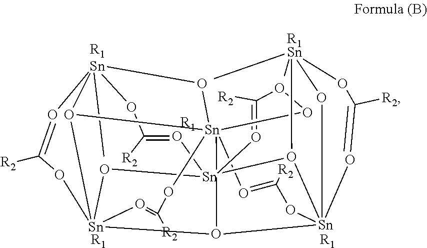
in the formula (B), R₁ represents —CH₃ or is represented by one of formulae (M-1) to (M-3): 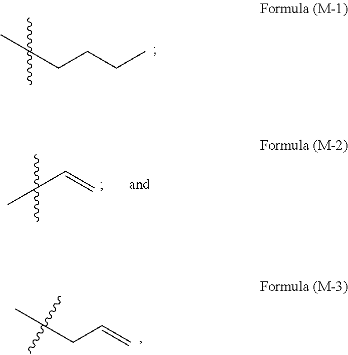
and in the formula (B), R₂ is represented by one of formulae (M-4) to (M-10):

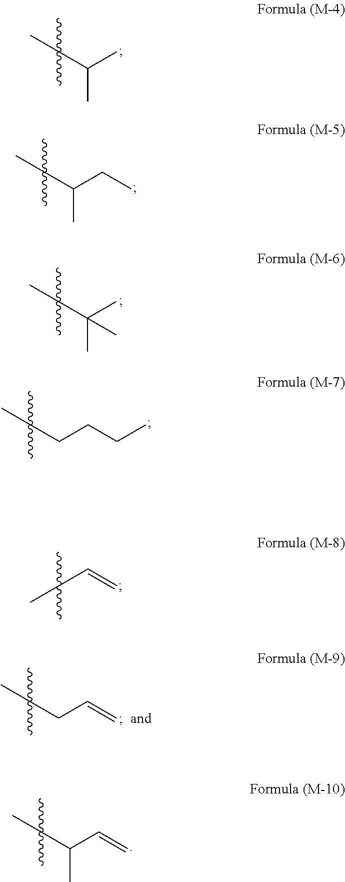

10. The photoresist composition of claim 1, wherein the second photosensitive material has a structure being more irregular than a structure of the first photosensitive material.

11. A method of forming a photoresist composition, comprising:
mixing a first photosensitive material and a second photosensitive material different from the first photosensitive material to form a curable composition, wherein the second photosensitive material is a 6Sn(vinyl)-2Cl cluster, a 5Sn-5Cl cluster, or a combination thereof, and the first photosensitive material is represented by formula (A) or formula (B): 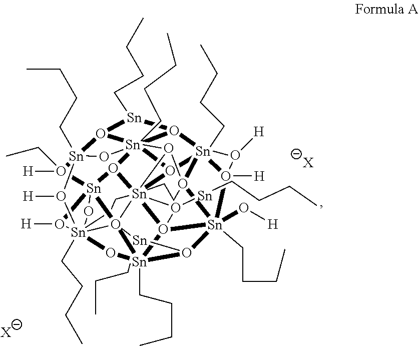
in the formula (A), X represents OH, Cl, Br, BF₄, 0.5C₂O₄, or RCO₂, and in the RCO₂, R has 1 to 15 carbon atoms, 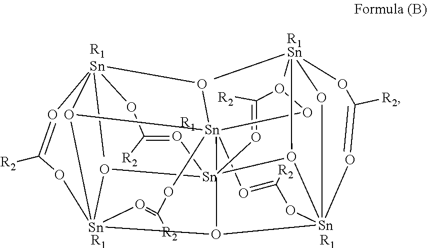
in the formula (B), R₁ represents —CH₃ or is represented by one of formulae (M-1) to (M-3): 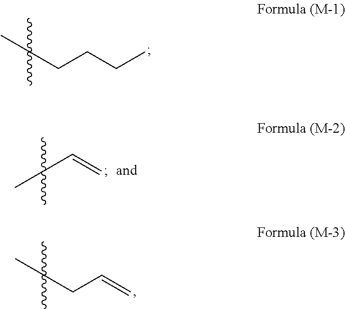
and in the formula (B), R₂ is represented by one of formulae (M-4) to (M-10): 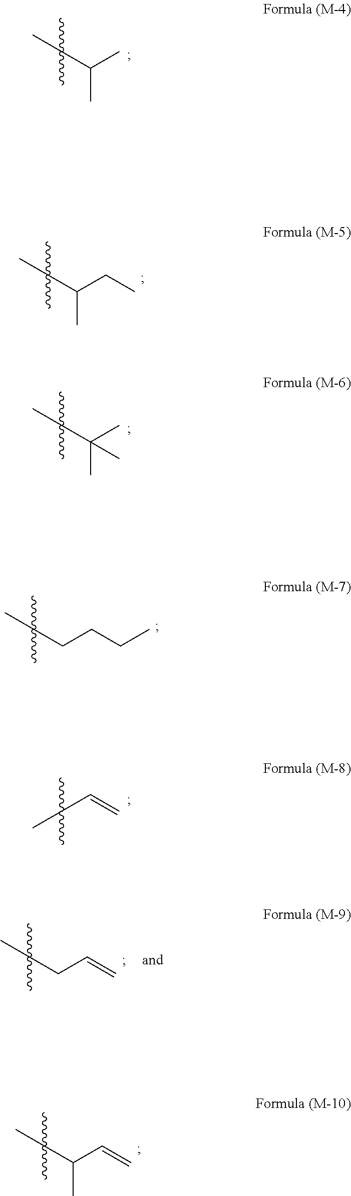
and dissolving the curable composition in a first solvent.

12. The method of claim 11, wherein the 6Sn(vinyl)-2Cl cluster is formed by reacting a first compound of formula (C-1): 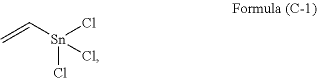
with a second compound of formula (C-2): 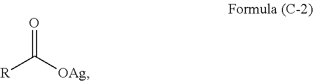
in the formula (C-2), R is represented by one of formulae (I-1) to (I-7): 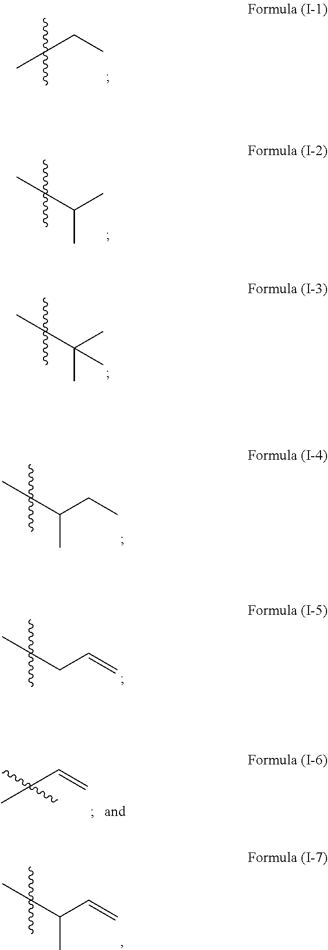
in a second solvent.

13. The method of claim 11, wherein the 5Sn-5 Cl cluster is formed by:
(2-1) reacting a first compound of formula (C-3): 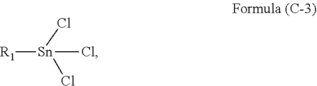
in the formula (C-3), R₁ is represented by formula (L-1): 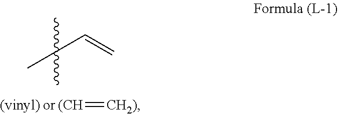
with a second compound of formula (C-4): 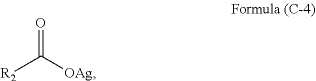
in the formula (C-4), R₂ is represented by one of formulae (K-1) to (K-6): 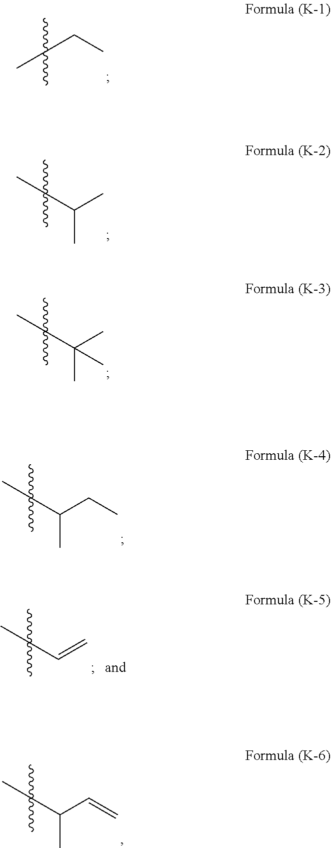
in a second solvent to obtain a substance; and
(2-2) recrystallizing the substance.

14. The method of claim 11, wherein the 5Sn-5Cl cluster is formed by:
(2-1′) reacting a first compound of formula (C-3′): 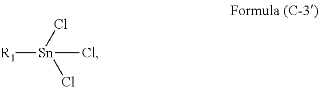
in the formula (C-3′), R₁ is represented by formula (L-2): 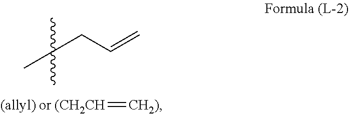
with a second compound of formula (C-4′): 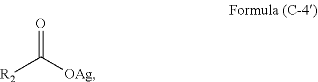
in the formula (C-4′), R₂ is represented by one of formulae (K-1) to (K-6): 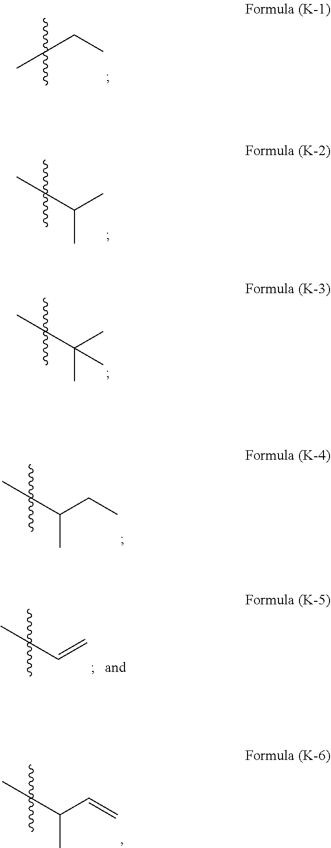
in a second solvent to obtain a substance; and
(2-2′) recrystallizing the substance.

15. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device; and
guiding the EUV radiation, by using one or more second optics, reflected from the reflective mask toward a photoresist coated substrate in the exposure device,
wherein the photoresist has a composition comprising:
a mixture comprising:
a first photosensitive material comprising a 6-Sn oxide cluster, a 12-Sn oxide cluster, or a combination thereof; and
a second photosensitive material comprising a 6Sn-2Cl cluster, a 5Sn-5Cl cluster, or a combination thereof.

16. The method of claim 15, wherein a weight percentage of the first photosensitive material in the mixture is in a range from 60% to 70%.

17. The method of claim 15, wherein a weight percentage of the second photosensitive material in the mixture is in a range from 30% to 40%.

18. The method of claim 15, wherein the second photosensitive material has a Sn-allyl unit or a Sn-vinyl unit.

19. The method of claim 15, wherein the second photosensitive material is represented by formula (2): 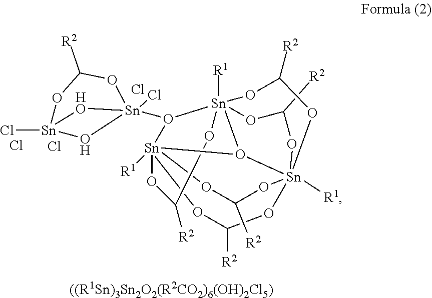
in the formula (2), R¹ is represented by formula (L-1): 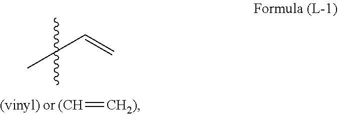
and in the formula (2), R² is represented by one of formulae (K-1) to (K-6):

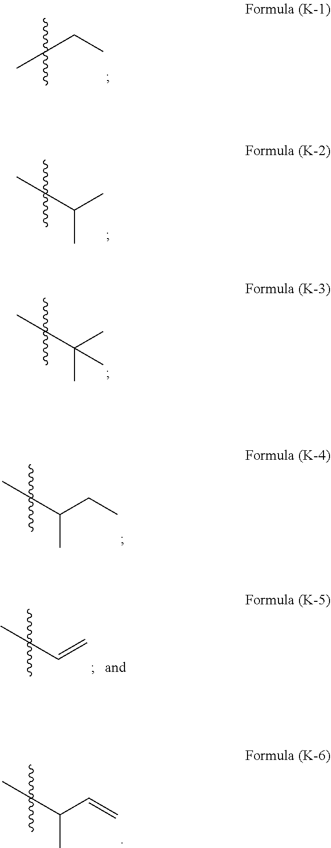

20. The method of claim 15, wherein the second photosensitive material is represented by formula (3): 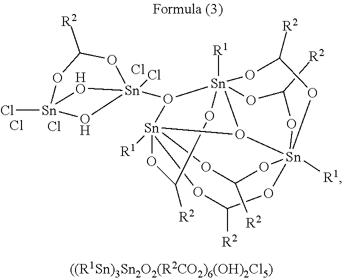
in the formula (3), R¹ is represented by formula (L-2): 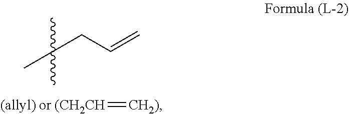
and in the formula (3) R² is represented by one of formulae (K-1) to (K-6): [chemical structure]
